(19) United States
(12) Patent Application Publication
(10) Pub. No.: US 2024/0147739 A1
(43) Pub. Date: May 2, 2024

(54) SEMICONDUCTOR MEMORY DEVICE, METHOD FOR MANUFACTURING THE SAME AND ELECTRONIC SYSTEM INCLUDING THE SAME

(71) Applicant: SAMSUNG ELECTRONICS CO., LTD., Suwon-si (KR)

(72) Inventors: Ji Hong KIM, Suwon-si (KR); Tae-Seok JANG, Suwon-si (KR); Hyun-Mook CHOI, Suwon-si (KR)

(21) Appl. No.: 18/208,979

(22) Filed: Jun. 13, 2023

(30) Foreign Application Priority Data
Nov. 2, 2022 (KR) 10-2022-0144154

(51) Int. Cl. H10B 63/00; H01L 23/00; H01L 25/00; H01L 25/065; H01L 25/18; H10B 80/00

(52) U.S. Cl. CPC H10B 63/845; H01L 24/08; H01L 24/80; H01L 25/0657; H01L 25/18; H01L 25/50; H10B 63/34; H10B 80/00; H01L 2224/08145; H01L 2224/80895; H01L 2224/80896; H01L 2924/1431; H01L 2924/1443

(57) ABSTRACT

A semiconductor memory device comprising a peripheral circuit structure and a cell structure stacked on the peripheral circuit structure, wherein the cell structure includes a cell substrate including a first face facing the peripheral circuit structure and a second face opposite the first face, a first mold stack including a plurality of first gate electrodes sequentially stacked on the first face, and a channel hole extending through the plurality of first gate electrodes. A channel structure includes a gate dielectric film, a semiconductor film, and a variable resistance film sequentially stacked in the channel hole, wherein the semiconductor film includes a sidewall portion intersecting the first face and the plurality of first gate electrodes, and a top plate portion extending from the sidewall portion in the cell substrate in a parallel manner to the first face.

### CROSS-REFERENCE TO RELATED APPLICATION

Korean Patent Application No. 10-2022-0144154, filed on Nov. 2, 2022, in the Korean Intellectual Property Office, is herein incorporated by reference in its entirety.

### BACKGROUND

### 1. Field

Embodiments relate to a semiconductor memory device, a method for manufacturing the same, and an electronic system including the same.

### 2. Description of Related Art

A semiconductor memory device capable of storing a high capacity of data therein may be used in an electronic system, and schemes for increasing a data storage capacity of the semiconductor memory device are being studied.

### SUMMARY

Embodiments are directed to semiconductor memory device. The semiconductor memory device may include a peripheral circuit structure, and a cell structure stacked on the peripheral circuit structure. The cell structure may include a cell substrate including a first face facing the peripheral circuit structure and a second face opposite the first face, a first mold stack including a plurality of first gate electrodes sequentially stacked on the first face, a channel hole extending through the plurality of first gate electrodes, a channel structure including a gate dielectric film, a semiconductor film, and a variable resistance film sequentially stacked in the channel hole. The semiconductor film may include a sidewall portion intersecting the first face and the plurality of first gate electrodes, and a top plate portion extending from the sidewall portion in the cell substrate in a parallel manner to the first face. The sidewall portion of the semiconductor film may extend linearly through the cell substrate and the first mold stack. The top plate portion of the semiconductor film may be exposed through the gate dielectric film and may be connected to the cell substrate.

Embodiments are also directed to a semiconductor memory device. The semiconductor device may include a peripheral circuit structure, and a cell structure stacked on the peripheral circuit structure. The cell structure may include a cell substrate including a first face facing the peripheral circuit structure and a second face opposite to the first face, a plurality of gate electrodes sequentially stacked on the first face, a semiconductor film intersecting the plurality of gate electrodes and connected to the cell substrate, a gate dielectric film extending along an outer side surface of the semiconductor film and interposed between the semiconductor film and the plurality of gate electrodes, and a variable resistance film extending along an inner side surface of the semiconductor film. The gate dielectric film may not extend along a surface of the semiconductor film parallel to the first face.

Embodiments are also directed to a method for manufacturing a semiconductor memory device. The method for manufacturing a semiconductor memory device may include forming a mold structure including a plurality of gate electrodes sequentially stacked on a base substrate, forming a channel structure intersecting the plurality of gate electrodes and connected to the base substrate. The channel structure may include a gate dielectric film, a semiconductor film, and a variable resistance film sequentially stacked, removing at least a portion of the base substrate to expose one end of the gate dielectric film, removing the exposed one end of the gate dielectric film to expose one end of the semiconductor film, and forming a cell substrate connected with the exposed one end of the semiconductor film.

### BRIEF DESCRIPTION OF DRAWINGS

Features will become apparent to those of skill in the art by describing in detail exemplary embodiments with reference to the attached drawings in which:

FIG. 1 is a block diagram of a semiconductor memory device according to example embodiments.

FIG. 2 is a circuit diagram of a semiconductor memory device according to example embodiments.

FIG. 3 is a schematic layout diagram of a semiconductor memory device according to example embodiments.

FIG. 4 is a cross-sectional view taken along A-A of FIG. 3.

FIG. 5A to FIG. 5E are various enlargements of a R1 area in FIG. 4.

FIG. 6A and FIG. 6B are diagrams of an operation of a semiconductor memory device according to example embodiments.

FIG. 7 is a cross-sectional view of a semiconductor memory device according to example embodiments.

FIG. 8 is an enlarged view of a R2 area of FIG. 7.

FIG. 9 is a cross-sectional view of a semiconductor memory device according to example embodiments.

FIG. 10 is an enlarged view of a R3 area of FIG. 9.

FIG. 11 to FIG. 25 are diagrams of stages in a method for manufacturing a semiconductor memory device according to example embodiments.

FIG. 26 and FIG. 27 are diagrams of stages in a method for manufacturing a semiconductor memory device according to example embodiments.

FIG. 28 is a block diagram of an electronic system according to example embodiments.

FIG. 29 is a perspective view of an electronic system according to example embodiments.

FIG. 30 is a schematic cross-sectional view taken along I-I of FIG. 29.

### DETAILED DESCRIPTION

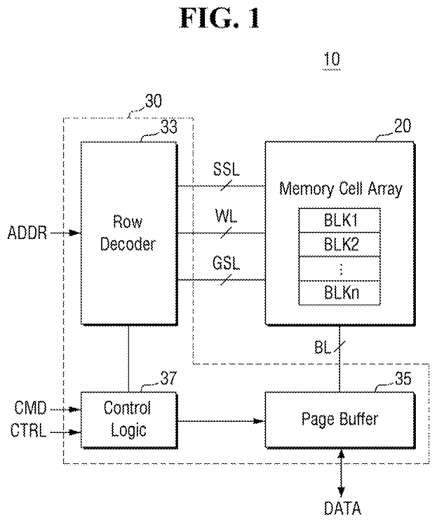

Hereinafter, referring to FIG. 1 to FIG. 10, a semiconductor memory device according to some embodiments is described.

FIG. 1 is a block diagram of a semiconductor memory device according to example embodiments.

Referring to FIG. 1, a semiconductor memory device 10 according to example embodiments may include a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. In an implementation, the memory cell blocks BLK1 to BLKn may be connected to a row decoder 33 via the word-line WL, the string select line SSL and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the semiconductor memory device 10, and may transmit and receive data DATA between the external device and the semiconductor memory device 10. The peripheral circuit 30 may include a control logic 37, the row decoder 33, and the page buffer 35. The peripheral circuit 30 may further include various sub-circuits such as an input/output circuit, a voltage generation circuit for generating various voltages required for an operation of the semiconductor memory device 10, and an error correction circuit for correcting an error of the data DATA read from the memory cell array 20.

The control logic 37 may be connected to the row decoder 33, the input/output circuit, and the voltage generation circuit. The control logic 37 may control overall operations of the semiconductor memory device 10. The control logic 37 may generate various internal control signals used in the semiconductor memory device 10 in response to the control signal CTRL. In an implementation, the control logic 37 may adjust a voltage level of a voltage supplied to the word-line WL and the bit-line BL when performing a memory operation such as a program operation or an erase operation.

The row decoder 33 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. In an implementation, when performing a program operation, the page buffer 35 may operate as the writer driver to apply a voltage based on the data DATA stored in the memory cell array 20 to the bit-line BL. On the other hand, when performing a read operation, the page buffer 35 may operate as the sense amplifier to detect the data DATA stored in the memory cell array 20.

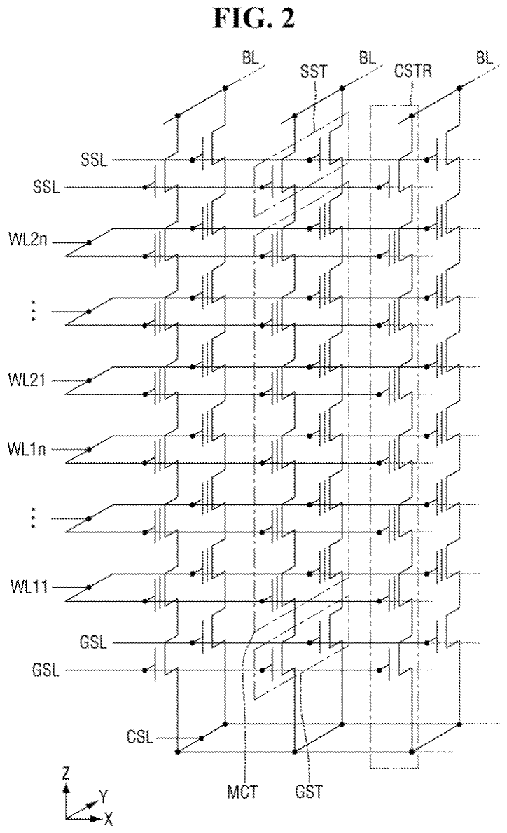

FIG. 2 is a circuit diagram of a semiconductor memory device according to example embodiments. Referring to FIG. 2, the memory cell array (e.g., 20 in FIG. 1) of the semiconductor memory device according to example embodiments may include a common source line CSL, a plurality of bit-lines BL, and a plurality of cell strings CSTR.

The plurality of bit-lines BL may be two-dimensionally arranged in a plane defined by the first direction X and the second direction Y. In an implementation, the bit-lines BL may be arranged and spaced apart from each other in the first direction X and extend in the second direction Y intersecting the first direction X. The plurality of cell strings CSTR may be connected in parallel to each of the bit-lines BL. The cell strings CSTR may be commonly connected to the common source line CSL. In an implementation, the plurality of cell strings CSTR may be between the bit-lines BL and the common source line CSL.

Each of the cell strings CSTR may include a ground select transistor GST connected to the common source line CSL, a string select transistor SST connected to the bit-line BL, and a plurality of memory cell transistors MCT between the ground select transistor GST and the string select transistor SST. Each of the memory cell transistors MCT may include a data storage element. The ground select transistor GST, the string select transistor SST and the memory cell transistors MCT may be connected in series to each other in the third direction Z. In accordance with the present disclosure, the first direction X, the second direction Y, and the third direction Z may be substantially perpendicular to each other.

The common source line CSL may be commonly connected to sources of the ground select transistors GST. Further, a ground select line GSL, a plurality of word-lines WL11 to WL1n and WL21 to WL2n, and a string select line SSL may be between the common source line CSL and the bit-line BL. The ground select line GSL may act as a gate electrode of the ground select transistor GST. The word-lines WL11 to WL1n and WL21 to WL2n may be respectively used as gate electrodes of the memory cell transistors MCT. The string select line SSL may act as a gate electrode of the string select transistor SST.

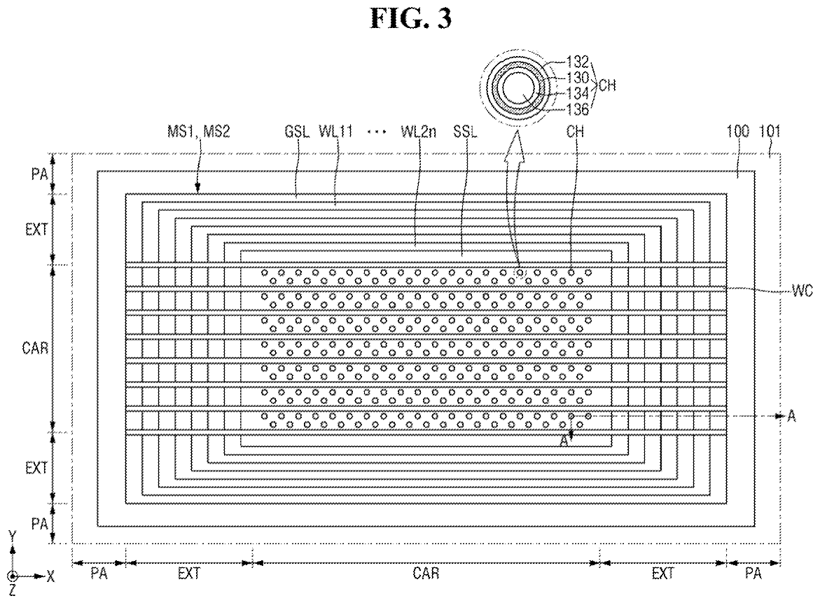

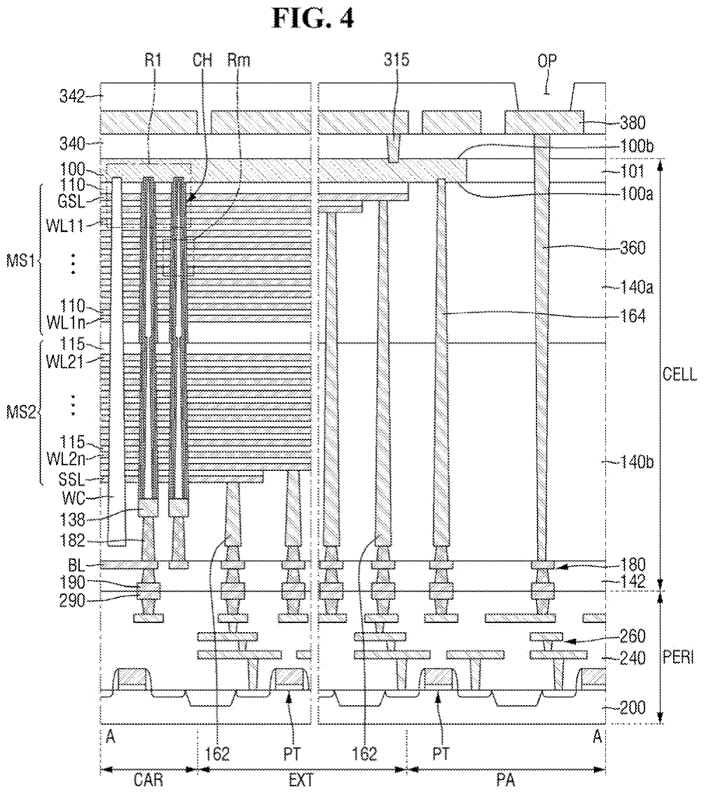

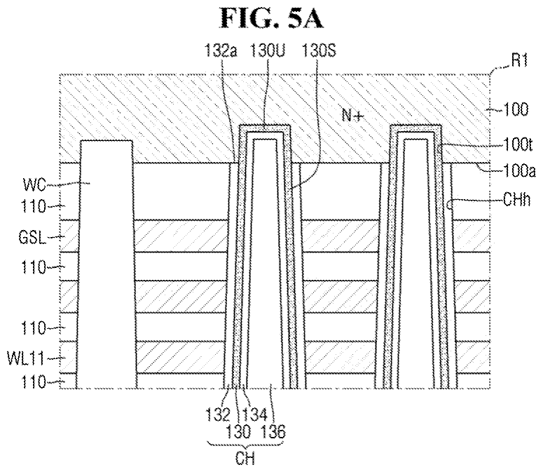

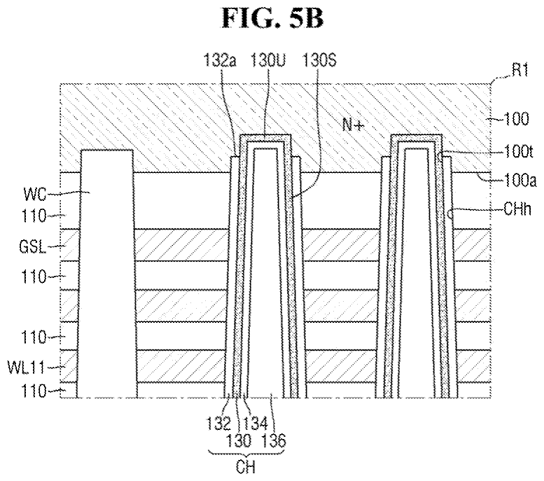

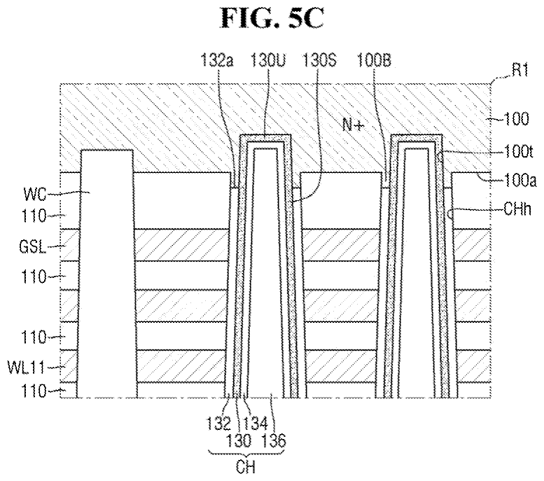

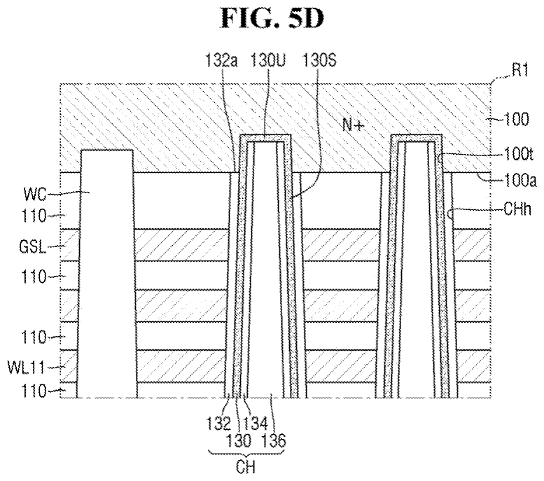

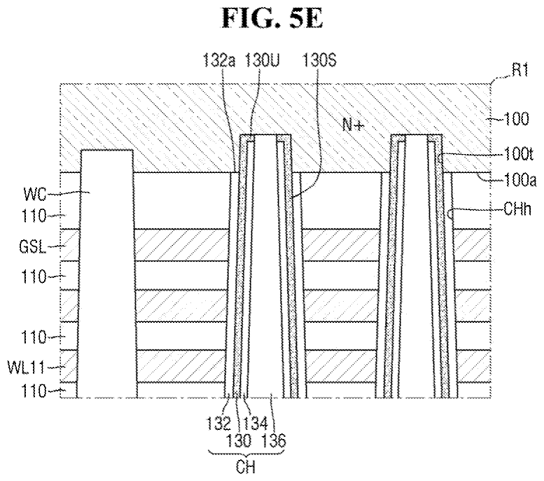

FIG. 3 is a schematic layout diagram of a semiconductor memory device according to example embodiments. FIG. 4 is a cross-sectional view taken along A-A of FIG. 3. FIG. 5A to FIG. 5E are various enlargements of a R1 area in FIG. 4. Referring to FIG. 3 to FIG. 5E, the semiconductor memory device according to example embodiments may include a cell structure CELL and a peripheral circuit structure PERI.

The cell structure CELL may include a cell substrate 100, an insulating substrate 101, a mold structure MS1 and MS2, interlayer insulating films 140a and 140b, a channel structure CH, a word-line cutting area WC, a bit-line BL, a gate contact 162 and a cell wiring structure 180.

The cell substrate 100 may include, e.g., a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate. As used herein, the term “or” is not an exclusive term, e.g., “A or B” would include A, B, or A and B.

In some embodiments, the cell substrate 100 may contain impurities. In an implementation, the cell substrate 100 may contain N-type impurities, such as phosphorus (P) or arsenic (As). In following description, an example in which the cell substrate 100 contains the N-type impurities is mainly described. However, this is only an example. In another example, the cell substrate 100 may contain P-type impurities. In some embodiments, the cell substrate 100 may include poly-Si doped with N-type impurities. The cell substrate 100 may act as a common source line (e.g., CSL in FIG. 2) of a semiconductor memory device according to some embodiments.

The cell substrate 100 may include a cell array area CAR and an extension area EXT. A memory cell array (e.g., 20 in FIG. 1) including a plurality of memory cells may be formed on the cell array area CAR. In an implementation, the channel structure CH, the gate electrodes GSL, WL11 to WL1n, WL21 to WL2n, and SSL, and the bit-line BL, which will be described later, may be on the cell array area CAR. In following description, a surface of the cell substrate 100 on which the memory cell array is disposed may be referred to as a first face 100a or a front face (a front side). Conversely, a surface of the cell substrate 100 opposite to the front face or the first face 100a of the cell substrate 100 may be referred to as a second face 100b or a rear face (a back side) of the cell substrate 100.

The extension area EXT may be defined around the cell array area CAR. In an implementation, the extension area EXT may surround the cell array area CAR in a plan view.

On the extension area EXT, the gate electrodes GSL, WL11 to WL1n, WL21 to WL2n, and SSL as described later may be stacked in a stepwise manner. The insulating substrate 101 may be formed around the cell substrate 100. The insulating substrate 101 may constitute an insulating area around the cell substrate 100. The insulating substrate 101 may include, e.g., silicon oxide, silicon nitride, silicon oxynitride, or silicon carbide.

A bottom face of the insulating substrate 101 may be coplanar with a bottom face of the cell substrate 100. However, this is only an example. In another example, a vertical level of the bottom face of the insulating substrate 101 may be lower than that of the bottom face of the cell substrate 100.

In some embodiments, the cell substrate 100 and/or the insulating substrate 101 may further include an outer area PA. The outer area PA may be defined outside the extension area EXT. In an implementation, the outer area PA may surround the extension area EXT in a plan view. A contact plug 360 as described below may be on the outer area PA.

The mold structure MS1 and MS2 may be formed on the first face 100a of the cell substrate 100. The mold structure MS1 and MS2 may include a plurality of gate electrodes GSL, WL11 to WL1n, WL21 to WL2n, and SSL, and a plurality of mold insulating films 110 and 115 stacked on the cell substrate 100. Each of the gate electrodes GSL, WL11 to WL1n, WL21 to WL2n, and SSL and each of the mold insulating films 110 and 115 may have a layered structure extending in parallel with the first face 100a of the cell substrate 100. The gate electrodes GSL, WL11 to WL1n, WL21 to WL2n, and SSL may be sequentially stacked on the cell substrate 100 while being spaced apart from each other via each of the mold insulating films 110 and 115.

In some embodiments, the mold structure MS1 and MS2 may include a plurality of stacks (e.g., the first mold stack MS1 and the second mold stack MS2) sequentially stacked on the cell substrate 100. Although the number of the stacks stacked on the cell substrate 100 may only be two, the number of the stacks stacked on the cell substrate 100 may be three or more.

The first mold stack MS1 may include first gate electrodes GSL, and WL11 to WL1n, and the first mold insulating films 110 that may be alternately stacked on top of each other while being on top of each other while being on the cell substrate 100. In some embodiments, the first gate electrodes GSL, and WL11 to WL1n may include a ground select line GSL and a plurality of first word-lines WL11 to WL1n sequentially stacked on the cell substrate 100. The number and the arrangement of the ground select line GSL and the first word-lines WL11 to WL1n are example embodiments.

The second mold stack MS2 may include second gate electrodes WL21 to WL2n, and SSL, and the second mold insulating films 115 alternately stacked on top of each other while being on top of each other while being on the first mold stack MS1. In some embodiments, the second gate electrodes WL21 to WL2n and SSL may include a plurality of second word-lines WL21 to WL2n and the string select line SSL sequentially stacked on the first mold stack MS1. The number and the arrangement of the second word-lines WL21 to WL2n and the string select line SSL are only example embodiments.

Each of the gate electrodes GSL, WL11 to WL1n, WL21 to WL2n, and SSL may include a conductive material, such as metals tungsten (W), molybdenum (Mo), ruthenium (Ru), cobalt (Co), or nickel (Ni), or semiconductor materials such as silicon. In one example, each of the gate electrodes GSL, WL11 to WL1n, WL21 to WL2n, and SSL may include tungsten (W), molybdenum (Mo), or ruthenium (Ru). In another example, each of the gate electrodes GSL, WL11 to WL1n, WL21 to WL2n, and SSL may include polysilicon.

Each of the mold insulating films 110 and 115 may include an insulating material, e.g., silicon oxide, silicon nitride, or silicon oxynitride. The interlayer insulating films 140a and 140b may be formed on the first face 100a of the cell substrate 100 and may cover the mold structure MS1 and MS2. In some embodiments, the interlayer insulating films 140a and 140b may include the first interlayer insulating film 140a and the second interlayer insulating film 140b sequentially stacked on the cell substrate 100. The first interlayer insulating film 140a may cover the first mold stack MS1, and the second interlayer insulating film 140b may cover the second mold stack MS2. Each of the interlayer insulating films 140a and 140b may include, e.g., silicon oxide, silicon oxynitride, or a low-k material with a lower dielectric constant than that silicon oxide.

The channel structure CH may be formed on the cell array area CAR of the cell substrate 100. The channel structure CH may extend in a vertical direction (hereinafter referred to as the third direction Z) intersecting the first face 100a of the cell substrate 100 and may extend through the mold structure MS1 and MS2. In an implementation, the channel structure CH may have a pillar shape (e.g., a cylinder shape) extending in the third direction Z. Accordingly, the channel structure CH may intersect the plurality of gate electrodes GSL, WL11 to WL1n, WL21 to WL2n, and SSL.

In some embodiments, the channel structure CH may have a step between the first mold stack MS1 and the second mold stack MS2. In an implementation, as shown in FIG. 4, a side surface of the channel structure CH may have a bent portion at a boundary between the first mold stack MS1 and the second mold stack MS2.

The channel structure CH may include a gate dielectric film 132, a semiconductor film 130, a variable resistance film 134, and a filling insulating film 136 sequentially stacked. In an implementation, a channel hole (e.g., CHh in FIGS. 5A to 5E) extending in the third direction Z and extending through the mold structure MS1 and MS2 may be formed. The gate dielectric film 132, the semiconductor film 130, the variable resistance film 134, and the filling insulating film 136 may be sequentially stacked in the channel hole CHh. In some embodiments, each of the gate dielectric film 132, the semiconductor film 130, and the variable resistance film 134 may conformally extend along a profile of the channel hole CHh. The filling insulating film 136 may fill an area of the channel hole CHh remaining after the channel hole CHh is filled with the gate dielectric film 132, the semiconductor film 130, and the variable resistance film 134.

The semiconductor film 130 may intersect the gate electrodes GSL, WL11 to WL1n, WL21 to WL2n, and SSL. Further, one end of the semiconductor film 130 may be connected to the cell substrate 100. The semiconductor film 130 may include, e.g., a semiconductor material such as monocrystalline silicon, polycrystalline silicon, organic semiconductor material, or carbon nanostructure. In one example, the semiconductor film 130 may include poly-silicon (poly-Si).

In some embodiments, the semiconductor film 130 may include a sidewall portion 130S and a top plate portion 130U. The sidewall portion 130S of the semiconductor film 130 may intersect the gate electrodes GSL, WL11 to WL1n, WL21 to WL2n, and SSL. The sidewall portion 130S may have a hollow structure. The sidewall portion 130S may have various shapes, e.g., a cylinder, a square column, or another polygonal column having a hollow space defined therein. The top plate portion 130U of the semiconductor film 130 may extend from a top of the sidewall portion 130S in a parallel manner to the first face 100a, e.g., in a XY plane. The sidewall portion 130S and the top plate portion 130U may constitute a semiconductor film 130 having an overall cup-shape.

In some embodiments, the semiconductor film 130 may extend through the first face 100a of the cell substrate 100. In an implementation, the cell substrate 100 may include a substrate trench 100t inwardly recessed from the first face 100a thereof. At least a portion (e.g., a top portion) of the semiconductor film 130 may conformally extend along a profile of the substrate trench 100t. The sidewall portion 130S of the semiconductor film 130 may intersect the first face 100a of the cell substrate 100 and the gate electrodes GSL, WL11 to WL1n, WL21 to WL2n, and SSL. The top plate portion 130U of the semiconductor film 130 may extend in a parallel manner to the first face 100a, e.g., in the XY plane, from the top of the sidewall portion 130S of the cell substrate 100 and may be connected to the cell substrate 100. The semiconductor film 130 may improve a contact area thereof with the cell substrate 100 to reduce a contact resistance.

In some embodiments, the sidewall portion 130S of the semiconductor film 130 may extend linearly through the cell substrate 100 and the first mold stack MS1. In an implementation, as shown in FIG. 5A to FIG. 5E, a side surface of the channel hole CHh and a side surface of the substrate trench 100t may continuously extend. In this case, a portion of the sidewall portion 130S of the semiconductor film 130 adjacent to a boundary between the cell substrate 100 and the first mold stack MS1 may be free of a step or a bent portion.

The gate dielectric film 132 may be interposed between the semiconductor film 130 and each of the gate electrodes GSL, WL11 to WL1n, WL21 to WL2n, and SSL. In an implementation, the gate dielectric film 132 may conformally extend along an outer side surface of the semiconductor film 130. Further, the gate dielectric film 132 may not cover one end of the semiconductor film 130. In an implementation, the gate dielectric film 132 may not cover the top plate portion 130U of the semiconductor film 130. In some embodiments, gate dielectric film 132 may not cover the top of the sidewall portion 130S of the semiconductor film 130. A surface of a portion of the semiconductor film 130 not covered with the gate dielectric film 132 may contact the cell substrate 100. When the semiconductor film 130 has a cup shape, the gate dielectric film 132 may be formed in an overall hollow cylindrical shape.

The gate dielectric film 132 may include, e.g., silicon oxide, silicon nitride, silicon oxynitride, or a high-k material having a higher dielectric constant than that of silicon oxide. The high dielectric constant material may include, e.g., aluminum oxide, hafnium oxide, lanthanum oxide, tantalum oxide, titanium oxide, lanthanum hafnium oxide, lanthanum aluminum oxide, or dysprosium scandium oxide.

In some embodiments, the gate dielectric film 132 may not extend along a surface of the semiconductor film 130 that is parallel to the first face 100a (e.g., extending in an XY plane). In an implementation, as shown in FIGS. 5A to 5E, the sidewall portion 130S of the semiconductor film 130 may extend linearly through the cell substrate 100 and the first mold stack MS1. The gate dielectric film 132 may extend only along the sidewall portion 130S of the semiconductor film 130. Further, the gate dielectric film 132 may not cover the top plate portion 130U of the semiconductor film 130. The gate dielectric film 132 may not overlap the semiconductor film 130 in the third direction Z.

A topmost surface 132a of the gate dielectric film 132 may have various vertical levels. In one example, as shown in FIG. 5A, the topmost surface 132a of the gate dielectric film 132 may be coplanar with the first face 100a of the cell substrate 100.

In another example, as shown in FIG. 5B, the topmost surface 132a of the gate dielectric film 132 may be positioned at a higher level than that of the first face 100a of the cell substrate 100. In an implementation, the topmost surface 132a of the gate dielectric film 132 may be positioned between the first face 100a of the cell substrate 100 and the top plate portion 130U of the semiconductor film 130.

In still another example, as shown in FIG. 5C, the topmost surface 132a of the gate dielectric film 132 may be positioned at a lower level than that of the first face 100a of the cell substrate 100. In an implementation, the topmost surface 132a of the gate dielectric film 132 may be positioned between the first face 100a of the cell substrate 100 and the ground select line GSL. In some embodiments, the cell substrate 100 may include a protrusion 100B. The protrusion 100B of the cell substrate 100 may protrude toward the gate dielectric film 132 from the first face 100a thereof. Further, the protrusion 100B may be interposed between the semiconductor film 130 and the first mold insulating film 110 and may contact the topmost surface 132a of the gate dielectric film 132. Thus, a contact area of the cell substrate with the semiconductor film 130 may be increased such that a contact resistance of the cell substrate 100 may be reduced.

The variable resistance film 134 may extend along an inner side surface of the semiconductor film 130. In an implementation, the variable resistance film 134 may conformally extend along an inner side surface of the sidewall portion 130S of the semiconductor film 130 and a bottom face of the top plate portion 130U of the semiconductor film 130. When the semiconductor film 130 has a cup shape, the variable resistance film 134 may be formed in a cup shape.

The variable resistance film 134 may include a variable resistive material. The variable resistive material may have variable resistance characteristics based on a current flowing through the variable resistance film 134. In an implementation, the variable resistance film 134 may include a material having switching characteristics, e.g., silicon oxide (SiOₓ), aluminum oxide (AlO), magnesium oxide (MgO), zirconium oxide (ZrO), hafnium oxide (HfO), silicon nitride (SiN), tungsten oxide (WO), titanium oxide (TiO) or tantalum oxide (TaO).

In some embodiments, the variable resistance film 134 may include a transition metal oxide (TMO). In one example, the variable resistance film 134 may include hafnium oxide (HfO) or tantalum oxide (TaO).

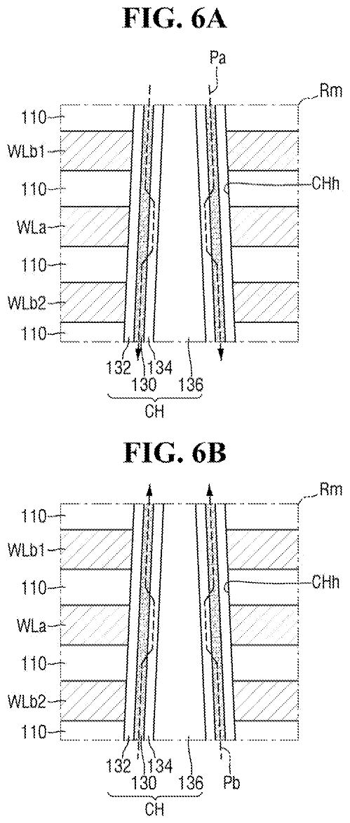

Areas of the variable resistance film 134 respectively facing the word-lines WL11 to WL1n and WL21 to WL2n may be capable of storing information, and may constitute memory cells. This will be described later in more detail in description with reference to FIGS. 6A and 6B.

The filling insulating film 136 may fill an area on the variable resistance film 134. In an implementation, the filling insulating film 136 may be formed to fill an inside of the cup-shaped variable resistance film 134. The filling insulating film 136 may be formed in a pillar shape, e.g., a cylindrical shape. The filling insulating film 136 may include an insulating material, e.g., silicon oxide, silicon nitride, or silicon oxynitride. In one example, the filling insulating film 136 may include silicon nitride (SiN).

In some embodiments, the filling insulating film 136 may extend through the first face 100a of the cell substrate 100. In an implementation, at least a portion (e.g., a top portion) of the filling insulating film 136 may fill an area of the substrate trench 100t remaining after the substrate trench 100t is filled with the semiconductor film 130 and the variable resistance film 134.

In some embodiments, the filling insulating film 136 may extend through the variable resistance film 134 and/or the semiconductor film 130. In one example, as shown in FIG. 5D, the filling insulating film 136 may extend through the variable resistance film 134 and contact the semiconductor film 130. In another example, as shown in FIG. 5E, the filling insulating film 136 may extend through the variable resistance film 134 and the semiconductor film 130 and contact the cell substrate 100.

In some embodiments, the channel structure CH may further include a channel pad 138. The channel pad 138 may be connected to the other end of the semiconductor film 130. The channel pad 138 may include, e.g., polysilicon doped with impurities of a first conductivity type (e.g., N-type).

In some embodiments, a plurality of channel structures CH may be arranged in a zigzag form. In an implementation, as shown in FIG. 3, the plurality of channel structures CH may be arranged in a staggered manner in each of the first direction X and the second direction Y. The plurality of channel structures CH arranged in the zigzag manner may further improve the integration of the semiconductor memory device. The number and the arrangement of the channel structures CH are example embodiments. In some further embodiments, the plurality of channel structures CH may be arranged in a honeycomb manner.

The word-line cutting area WC may extend in the first direction X and may cut the mold structure MS1 and MS2. The mold structure MS1 and MS2 may be divided into portions respectively constituting a plurality of memory cell blocks (e.g., BLK1 to BLKn in FIG. 1) via the word-line cutting areas WC. The word-line cutting area WC may include an insulating material, e.g., silicon oxide, silicon nitride, or silicon oxynitride.

A plurality of word-line cutting areas WC may be two-dimensionally arranged in a plane including the first direction X and the second direction Y. In an implementation, the word-line cutting areas WC may extend in the first direction X, and may be spaced apart from each other and arranged along the second direction Y.

The bit-line BL may be formed on the mold structure MS1 and MS2. The bit-line BL may extend in the second direction Y and may be connected to the plurality of channel structures CH arranged along the second direction Y. In an implementation, a bit-line contact 182 connected to the channel pad 138 may be in the second interlayer insulating film 140b. The bit-line BL may be electrically connected to the channel structures CH via the bit-line contact 182.

A plurality of bit-lines BL may be two-dimensionally arranged in a plane including the first direction X and the second direction Y. In an implementation, the bit-lines BL may extend in the second direction Y, and may be spaced apart from each other and arranged along the first direction X.

In some embodiments, the bit-line BL may be interposed between the peripheral circuit structure PERI and the channel structure CH. The gate contact 162 may be connected to each of the gate electrodes GSL, WL11 to WL1n, WL21 to WL2n, and SSL. In an implementation, each of a plurality of gate contacts 162 may extend through the interlayer insulating films 140a and 140b in the third direction Z and may be connected to corresponding one of the gate electrodes GSL, WL11 to WL1n, WL21 to WL2n, and SSL.

The cell wiring structure 180 may be formed on the mold structure MS1 and MS2. In an implementation, a first inter-wiring insulating film 142 may be formed on the second interlayer insulating film 140b, and the cell wiring structure 180 may be formed within the first inter-wiring insulating film 142. The cell wiring structure 180 may be electrically connected to the bit-lines BL and the gate contacts 162. Thus, the cell wiring structure 180 may be electrically connected to the channel structure CH and the gate electrodes GSL, WL11 to WL1n, WL21 to WL2n, and SSL. The number of layers and the arrangement of the cell wiring structure 180 as illustrated are example embodiments.

In some embodiments, a first source contact 164 connecting the cell substrate 100 and the cell wiring structure 180 to each other may be formed. The first source contact 164 may extend through the interlayer insulating films 140a and 140b, e.g., in the third direction Z and electrically connect the cell substrate 100 and the cell wiring structure 180 to each other. In some further embodiments, the first source contact 164 may be omitted.

The peripheral circuit structure PERI may include a peripheral circuit substrate 200, a peripheral circuit element PT, and a peripheral circuit wiring structure 260. The peripheral circuit substrate 200 may include, e.g., a semiconductor substrate such as a silicon substrate, a germanium substrate, or a silicon-germanium substrate. Alternatively, the peripheral circuit substrate 200 may include a silicon-on-insulator (SOI) substrate or a germanium-on-insulator (GOI) substrate.

The peripheral circuit element PT may be formed on the peripheral circuit substrate 200. The peripheral circuit element PT may constitute a peripheral circuit (e.g., 30 in FIG. 1) that may control an operation of the semiconductor memory device. In an implementation, the peripheral circuit element PT may include a control logic (e.g., 37 in FIG. 1), a row decoder (e.g., 33 in FIG. 1), and a page buffer (e.g., 35 in FIG. 1). In following description, a surface of the peripheral circuit substrate 200 on which the peripheral circuit element PT may be disposed may be referred to as a front face (front side) of the peripheral circuit substrate 200. Conversely, a surface of the peripheral circuit substrate 200 opposite to the front face of the peripheral circuit substrate 200 may be referred to as a rear face (back side) of the peripheral circuit substrate 200.

The peripheral circuit element PT may include, e.g., a transistor. In an implementation, the peripheral circuit element PT may include not only various active elements such as transistors, but also various passive elements such as capacitors, resistors, and inductors.

The peripheral circuit wiring structure 260 may be formed on the peripheral circuit element PT. In an implementation, a second inter-wiring insulating film 240 may be formed on the front face of the peripheral circuit substrate 200. The peripheral circuit wiring structure 260 may be formed within the second inter-wiring insulating film 240. The peripheral circuit wiring structure 260 may be electrically connected to the peripheral circuit element PT. The number of layers and the arrangement of the peripheral circuit wiring structure 260 as illustrated are example embodiments.

In some embodiments, the cell structure CELL may be stacked on the peripheral circuit structure PERI. In an implementation, the cell structure CELL may be stacked on the second inter-wiring insulating film 240.

In some embodiments, the first face 100a of the cell substrate 100 may face the peripheral circuit structure PERI. In an implementation, the front face of the cell substrate 100, that is, the first face 100a thereof may face the front face of the peripheral circuit substrate 200.

The semiconductor memory device may have a C2C (chip to chip) structure. The C2C structure may be manufactured by forming an upper chip including the cell structure CELL on a first wafer (e.g., the cell substrate 100), and then forming a lower chip including the peripheral circuit structure PERI on a second wafer (e.g., the peripheral circuit substrate 200) different from the first wafer, and then connecting the upper chip and the lower chip to each other in a bonding scheme.

In one example, the bonding scheme may refer to a scheme in which a first bonding metal 190 as the uppermost metal layer of the upper chip and a second bonding metal 290 as the uppermost metal layer of the lower chip are electrically connected to each other. In an implementation, when each of the first bonding metal 190 and the second bonding metal 290 are made of copper (Cu), the bonding scheme may be a Cu—Cu bonding scheme. In another example, each of the first bonding metal 190 and the second bonding metal 290 may be made of various other metals such as aluminum (Al) or tungsten (W).

As the first bonding metal 190 and the second bonding metal 290 are bonded to each other, the cell wiring structure 180 may be connected to the peripheral circuit wiring structure 260. Thus, the bit-line BL and/or each of the gate electrodes ECL, GSL, WL11 to WL1n, WL21 to WL2n, and SSL may be electrically connected to the peripheral circuit element PT.

In some embodiments, an input/output wiring structure 380 may be formed on the second face 100b of the cell substrate 100. In an implementation, a third interlayer insulating film 340 covering the cell substrate 100 and the insulating substrate 101 may be formed on the second face 100b of the cell substrate 100. The input/output wiring structure 380 may be formed on the third interlayer insulating film 340. The number of layers and the arrangement of the input/output wiring structure 380 as illustrated are example embodiments. The third interlayer insulating film 340 may include, e.g., silicon oxide, silicon oxynitride, or a low-k material with a lower dielectric constant than that of silicon oxide.

The input/output wiring structure 380 may be electrically connected to the cell structure CELL and/or the peripheral circuit structure PERI. In some embodiments, a second source contact 315 connecting the cell substrate 100 and the input/output wiring structure 380 to each other may be formed. The second source contact 315 may extend through the third interlayer insulating film 340, e.g., in the third direction Z and may electrically connect the cell substrate 100 and the input/output wiring structure 380 to each other. The second source contact 315 may include, e.g., metal such as tungsten (W), cobalt (Co), or nickel (Ni). In some further embodiments, the second source contact 315 may be omitted.

In some embodiments, a width of the second source contact 315 may decrease as the second source contact 315 extends toward the cell substrate 100. This may be due to characteristics of an etching process for forming the second source contact 315.

In some embodiments, the contact plug 360 connecting the cell wiring structure 180 and the input/output wiring structure 380 to each other may be formed. The contact plug 360 may be formed on the outer area PA. In an implementation, the contact plug 360 may extend through the third interlayer insulating film 340, the insulating substrate 101, the first interlayer insulating film 140a, and the second interlayer insulating film 140b in the third direction Z. The cell wiring structure 180 may be electrically connected to the input/output wiring structure 380 via the contact plug 360.

In some embodiments, a width of the contact plug 360 may decrease as the contact plug 360 extends toward the cell wiring structure 180. This may be due to characteristics of an etching process for forming the contact plug 360.

In some embodiments, a capping insulating film 342 covering the input/output wiring structure 380 may be formed. In an implementation, the capping insulating film 342 may have a pad opening OP defined therein exposing a portion of the input/output wiring structure 380. The portion of the input/output wiring structure 380 exposed through the pad opening OP may act as an input/output pad (I/O pad).

FIG. 6A and FIG. 6B are diagrams of an operation of a semiconductor memory device according to example embodiments. For reference, FIG. 6A and FIG. 6B are respectively enlarged views to illustrate a Rm area of FIG. 4.

Referring to FIG. 4 and FIG. 6A, a program operation may be performed. In an implementation, a word-line (hereinafter, a select word-line WLa) facing an area of the variable resistance film 134 into which data is programmed may be selected, while the remaining word-lines (hereinafter, non-selected word-lines WLb1 and WLb2) may not be selected. In an implementation, the select word-line WLa may be turned off, and the non-selected word-lines WLb1 and WLb2 may be turned on. In one example, a voltage of about 5 to 6V may be applied to the bit-line BL, and a ground voltage may be applied to the cell substrate 100 acting as the common source line (e.g., CSL in FIG. 2). At this time, a voltage of 0V or a negative value may be applied to the selected word-line WLa, while a voltage (e.g., a voltage of about 6V) higher than a threshold voltage may be applied to the non-selected word-lines WLb1 and WLb2.

In this case, carriers (e.g., electrons) may flow along a first path Pa. In an implementation, the electrons may flow along a portion of the semiconductor film 130 facing the first non-selected word-line WLb1 and then may shift to and flow along a portion of the variable resistance film 134 facing the select word-line WLa, and then may shift to and flow along a portion of the semiconductor film 130 facing the second non-selected word-line WLb2 and then may flow toward the bit-line BL. Thus, the current selectively flows in an area of the variable resistance film 134 facing the select word-line WLa, such that a resistance of the variable resistance film 134 in that area may change. In an implementation, the resistance of the area of the variable resistance film 134 facing the select word-line WLa may be lowered. In this program operation, the area of the variable resistance film 134 facing the select word-line WLa may be set to a set state.

Referring to FIG. 4 and FIG. 6B, an erase operation may be performed. In an implementation, a word-line (hereinafter, a select word-line WLa) facing an area of the variable resistance film 134 from which data is erased may be selected, while the remaining word-lines (hereinafter, non-selected word-lines WLb1 and WLb2) may not be selected. In an implementation, the select word-line WLa may be turned off, and the non-selected word-lines WLb1 and WLb2 may be turned on. In one example, a ground voltage may be applied to the bit-line BL, while a voltage of about 5 to 6V may be applied to the cell substrate 100 acting as the common source line (e.g., CSL in FIG. 2). At this time, a voltage of 0V or a negative value may be applied to the selected word-line WLa, and a voltage (e.g., about 6V) higher than a threshold voltage may be applied to the non-selected word-lines WLb1 and WLb2.

In this case, carriers such as electrons may flow along a second path Pb. In an implementation, the electrons may flow along an area of the semiconductor film 130 facing the second non-selected word-line WLb2, and then may shift to and flow along an area of the variable resistance film 134 facing the select word-line WLa, and then shift to and flow along an area of the semiconductor film 130 facing the first non-selected word-line WLb1 and then may flow toward the cell substrate 100. Thus, the current may selectively flow in the area of the variable resistance film 134 facing the select word-line WLa, such that the resistance of the variable resistance film 134 in that area may change. In an implementation, the resistance of the area of the variable resistance film 134 facing the select word-line WLa may be increased. In the erase operation, the area of the variable resistance film 134 facing the select word-line WLa may be set to a reset state.

In the semiconductor memory device, in order to secure a connection path between the cell string (e.g., CSTR in FIG. 2) and the common source line (e.g., CSL in FIG. 2), a common source line (hereinafter, referred to as a side surface connection source structure) connected to a side surface of the semiconductor film (e.g., 130 of FIG. 5A to FIG. 5E) may be used as a channel. However, the side surface connection source structure has a problem of a high process cost.

Alternatively, the semiconductor memory device according to some embodiments may have a C2C structure. Thus, the common source line may be easily formed. In an implementation, as described above, the upper chip and the lower chip may be connected to each other in a bonding scheme in the C2C structure. Thus, the semiconductor film 130 used as a channel may be easily exposed by a planarization process (e.g., a CMP process (chemical mechanical polishing process) on a wafer (e.g., the first wafer) of the upper chip. Thus, in the C2C structure, the common source line (that is, the cell substrate 100) connected to the semiconductor film 130 may be formed more easily.

In a semiconductor memory device including three-dimensionally arranged memory cells, a CTF (charge trap flash) scheme may be used. However, in the semiconductor memory device using the CTF scheme, integration may be limited due to interference between memory cells. Therefore, as an alternative to this scheme, a memory device may have a variable resistance characteristic, e.g., a resistive random access memory (RRAM), a phase change random access memory (PRAM), or a magnetic random access memory (MRAM). This memory device may reduce a thickness between layers compared to the CTF scheme and may improve the memory capacity.

As described above, in the semiconductor memory device according to some embodiments, the channel structure CH including the variable resistance film 134 may constitute the memory cells. Thus, the semiconductor memory device with improved integration and memory capacity compared to a semiconductor memory device using the CTF scheme may be provided.

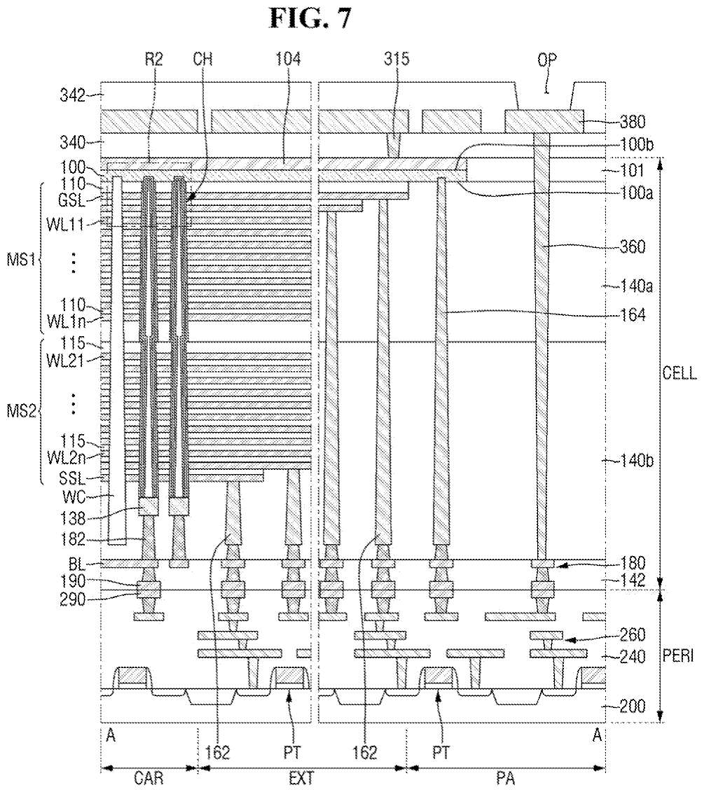

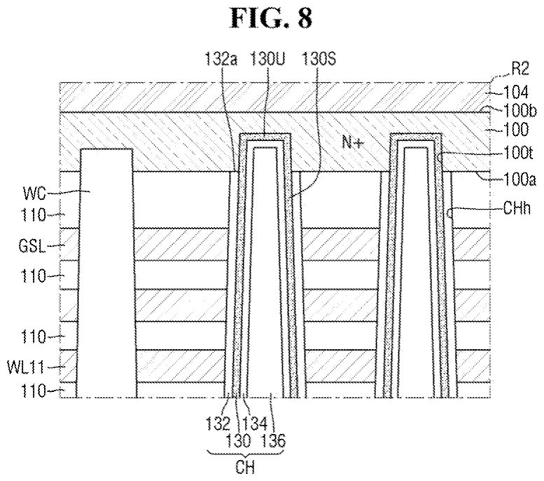

FIG. 7 is a cross-sectional view of a semiconductor memory device according to example embodiments. FIG. 8 is an enlarged view of a R2 area of FIG. 7. For convenience of description, those duplicate with descriptions as set forth above with reference to FIG. 1 to FIG. 6B are briefly described or omitted.

Referring to FIG. 7 and FIG. 8, the semiconductor memory device according to example embodiments may further include a conductive plate 104. The conductive plate 104 may extend along the second face 100b of the cell substrate 100. The conductive plate 104 may be electrically connected to the cell substrate 100. In an implementation, a bottom face of the conductive plate 104 may contact the second face 100b of the cell substrate 100. The conductive plate 104 may include a conductive material, e.g., metal such as tungsten (W), cobalt (Co), or nickel (Ni), or metal silicide. This conductive plate 104 may be used to reduce the electrical resistance of the common source line (e.g., CSL in FIG. 2) including the cell substrate 100.

A top face of the conductive plate 104 may be coplanar with the top face of the insulating substrate 101. In another example, a vertical level of the top face of the conductive plate 104 may be higher than that of the top face of the insulating substrate 101.

In some embodiments, the second source contact 315 may be connected to the conductive plate 104. In an implementation, the second source contact 315 may extend through the third interlayer insulating film 340 and may electrically connect the input/output wiring structure 380 and the conductive plate 104 to each other.

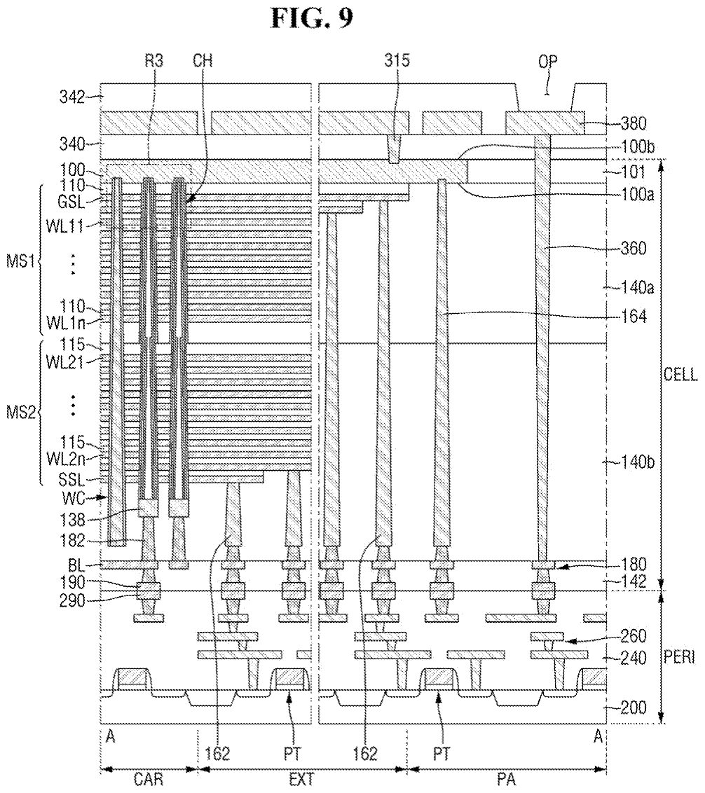

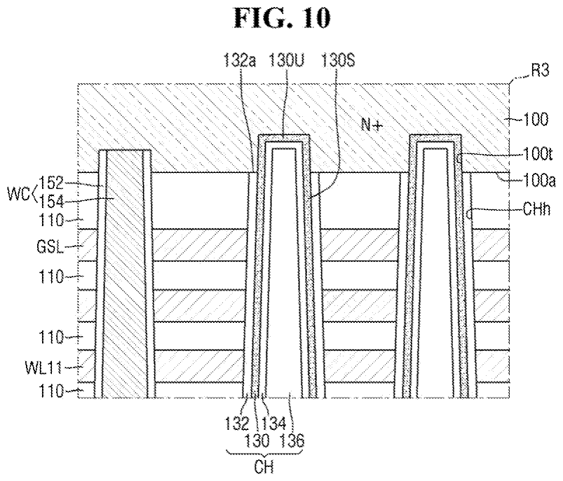

FIG. 9 is a cross-sectional view of a semiconductor memory device according to example embodiments. FIG. 10 is an enlarged view of a R3 area of FIG. 9. For convenience of description, those duplicate with descriptions as set forth above with reference to FIG. 1 to FIG. 6B are briefly described or omitted.

Referring to FIG. 9 and FIG. 10, in the semiconductor memory device according to some embodiments, the word-line cutting area WC may include an insulating spacer 152 and a conductive pattern 154. The conductive pattern 154 may be connected to the cell substrate 100. In an implementation, the conductive pattern 154 may extend in the third direction Z and extend through the mold structure MS1 and MS2 and may be connected to the cell substrate 100. In some embodiments, the conductive pattern 154 may electrically connect the cell substrate 100 and the cell wiring structure 180 to each other.

The insulating spacer 152 may extend along a side surface of the conductive pattern 154. The insulating spacer 152 may include an insulating material, e.g., silicon oxide, aluminum oxide, or tantalum oxide. The insulating spacer 152 may electrically insulate the conductive pattern 154 from each of the gate electrodes ECL, GSL, WL11 to WL1n, WL21 to WL2n, and SSL.

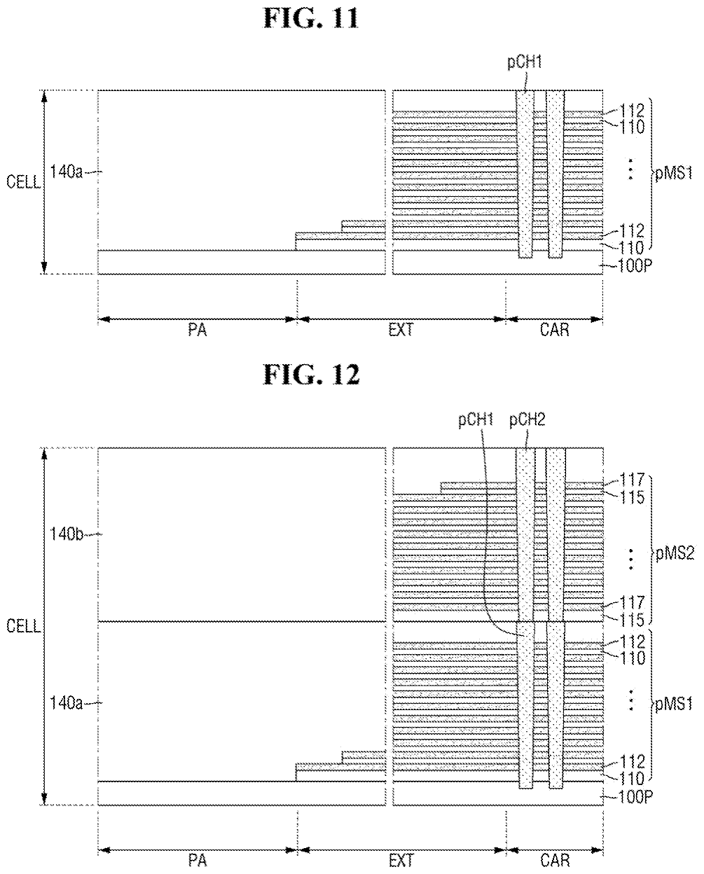

Hereinafter, with reference to FIG. 1 to FIG. 27, a method for manufacturing a semiconductor device according to some embodiments is described. FIG. 11 to FIG. 25 are diagrams of stages in a method for manufacturing a semiconductor memory device according to example embodiments. For the convenience of description, those duplicate with descriptions as set forth above with reference to FIG. 1 to FIG. 10 are briefly described or omitted.

Referring to FIG. 11, a first pre-mold pMS1 and a first pre-channel pCH1 are formed on a base substrate 100P. The first pre-mold pMS1 may be formed on the front face of the base substrate 100P.

The first pre-mold pMS1 may include a plurality of first mold insulating films 110 and a plurality of first mold sacrificial films 112 alternately stacked on top of each other while being on the base substrate 100P. The first mold sacrificial film 112 may include a material having an etch selectivity with respect to that of the first mold insulating film 110. In one example, the first mold insulating film 110 may include a silicon oxide film, and the first mold sacrificial film 112 may include a silicon nitride film.

The first pre-mold pMS1 on the extension area EXT may be patterned in a stepped manner. Accordingly, the first pre-mold pMS1 may be stacked in a stepwise manner.

The first pre-channel pCH1 may extend through the first pre-mold pMS1 on the cell array area CA. Further, the first pre-channel pCH1 may be connected to the base substrate 100P. In an implementation, the first interlayer insulating film 140a covering the first pre-mold pMS1 may be formed on the base substrate 100P. The first pre-channel pCH1 may extend through the first interlayer insulating film 140a and the first pre-channel pCH1 connected to the base substrate 100P.

The first pre-channel pCH1 may include a material having an etch selectivity with respect to that of each of the first mold insulating film 110 and the first mold sacrificial film 112. In one example, the first pre-channel pCH1 may include poly silicon. In some embodiments, the first pre-channel pCH1 may extend through a front face of the base substrate 100P. In an implementation, a vertical level of a bottom face of the first pre-channel pCH1 may be lower than that of a top face of the base substrate 10013.

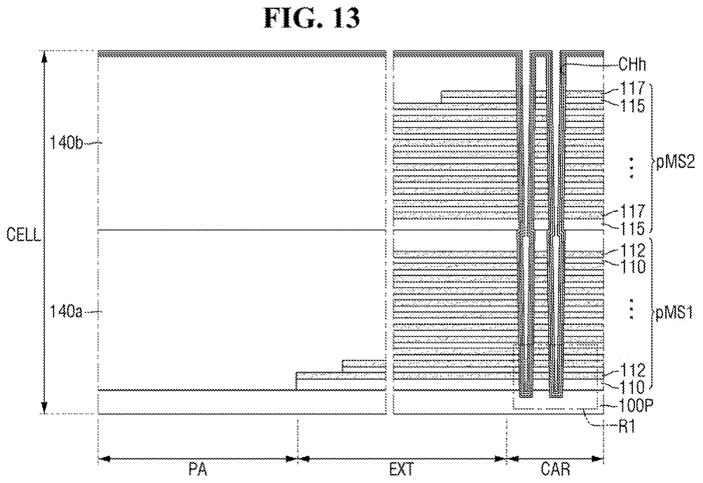

Referring to FIG. 12, a second pre-mold pMS2 and a second pre-channel pCH2 are formed on the first pre-mold pMS1. The second pre-mold pMS2 may include a plurality of second mold insulating films 115 and a plurality of second mold sacrificial films 117 alternately stacked on top of each other while being on the first pre-mold pMS1. Since forming the second pre-mold pMS2 may be similar to forming the first pre-mold pMS1, a detailed description thereof is omitted below.

The second pre-channel pCH2 may extend through the second pre-mold pMS2 on the cell array area CA. Further, the second pre-channel pCH2 may be connected to the first pre-channel pCH1. Forming the second pre-channel pCH2 may be similar to forming the first pre-channel pCH1, and thus, a detailed description thereof is omitted below.

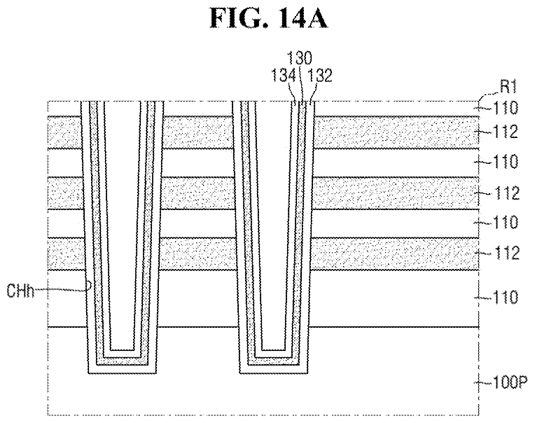

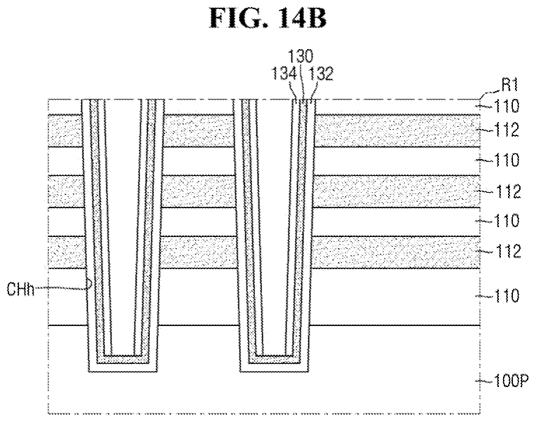

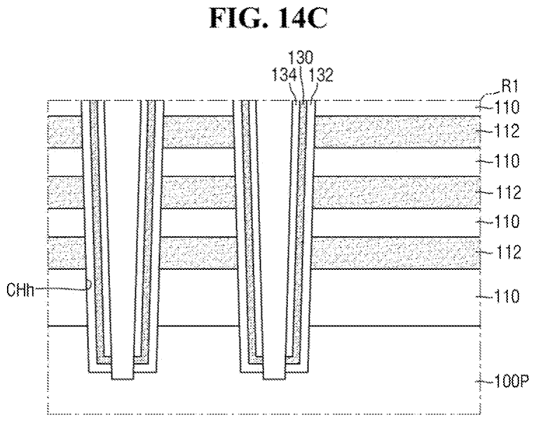

Referring to FIG. 13 and FIG. 14A to FIG. 14C, the gate dielectric film 132, the semiconductor film 130, and the variable resistance film 134 may be sequentially stacked. For reference, FIG. 14A to FIG. 14C are various enlarged views to illustrate a R1 area in FIG. 13.

In an implementation, the first pre-channel pCH1 and the second pre-channel pCH2 may be selectively removed. As the first pre-channel pCH1 and the second pre-channel pCH2 are removed, the channel hole CHh extending in the third direction Z and extending through the first pre-mold pMS1 and the second pre-mold pMS2 may be formed. The gate dielectric film 132, the semiconductor film 130, and the variable resistance film 134 may be sequentially stacked in the channel hole CHh. In some embodiments, each of the gate dielectric film 132, the semiconductor film 130, and the variable resistance film 134 may conformally extend along the profile of the channel hole CHh.

In some embodiments, the variable resistance film 134 may be in the channel hole CHh, and then, an etching process for forming a hole extending through the variable resistance film 134 may be performed. In an implementation, referring to FIG. 14B, at least a portion of a lower portion of the variable resistance film 134 may be removed by the etching process. Thus, the variable resistance film 134 as described above using FIG. 5D may be provided.

In some embodiments, after the variable resistance film 134 is formed in the channel hole CHh, an etching process for forming a hole extending through the variable resistance film 134, the semiconductor film 130, and/or the gate dielectric film 132 may be performed. In an implementation, referring to FIG. 14C, at least a portion of a lower portion of the variable resistance film 134, at least a portion of a lower portion of the semiconductor film 130, and at least a portion of a lower portion of the gate dielectric film 132 may be removed by the etching process. Thus, the semiconductor film 130 and the variable resistance film 134 as described above using FIG. 5E may be provided.

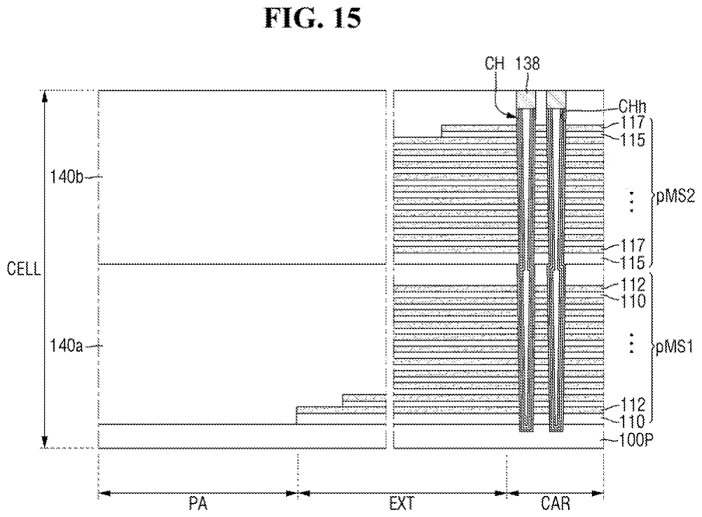

Referring to FIG. 15, the channel structure CH may be formed. In an implementation, the filling insulating film 136 may be formed on the variable resistance film 134. The filling insulating film 136 may fill an area of the channel hole CHh remaining after the channel hole CHh has been filled with the gate dielectric film 132, the semiconductor film 130, and the variable resistance film 134. Subsequently, the channel pad 138 connected to the other end of the semiconductor film 130 may be formed. Thus, the channel structure CH including the gate dielectric film 132, the semiconductor film 130, the variable resistance film 134, the filling insulating film 136, and the channel pad 138 may be formed.

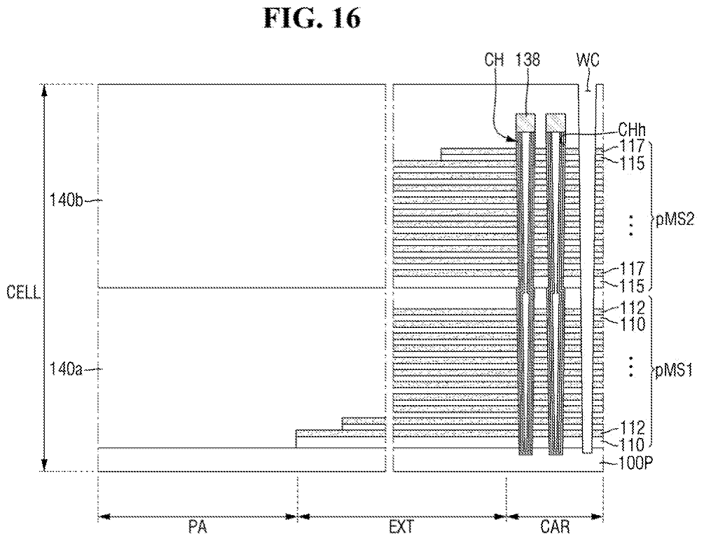

Referring to FIG. 16, the word-line cutting area WC may be formed. The word-line cutting area WC may extend in the first direction (e.g., X in FIG. 3) and may cut the first pre-mold pMS1 and the second pre-mold pMS2. In some embodiments, the word-line cutting area WC may extend through the front face of the base substrate 100P. In an implementation, a bottom face of the word-line cutting area WC may be positioned at a vertical level lower than that of the top face of the base substrate MP.

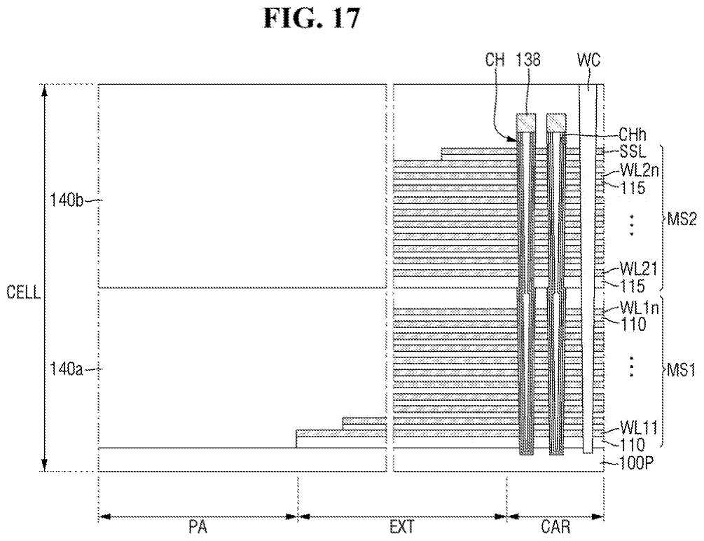

Referring to FIG. 17, the plurality of gate electrodes GSL, WL11 to WL1n, WL21 to WL2n, and SSL may be formed. In an implementation, the mold sacrificial films 112 and 117 exposed through the word-line cutting area WC may be selectively removed. Subsequently, the gate electrodes GSL, WL11 to WL1n, WL21 to WL2n, and SSL respectively filling spaces obtained via the removal of the mold sacrificial films 112 and 117 may be formed. Thus, the first mold stack MS1 including the plurality of first gate electrodes GSL and WL11 to WL1n and the second mold stack MS2 including the plurality of second gate electrodes WL21 to WL2n and SSL may be formed.

After the first mold stack MS1 and the second mold stack MS2 have been formed, the word-line cutting area WC may be filled with an insulating material. In some further embodiments, the word-line cutting area WC may be filled with the insulating spacer 152 and the conductive pattern 154 as described above using FIG. 9 and FIG. 10.

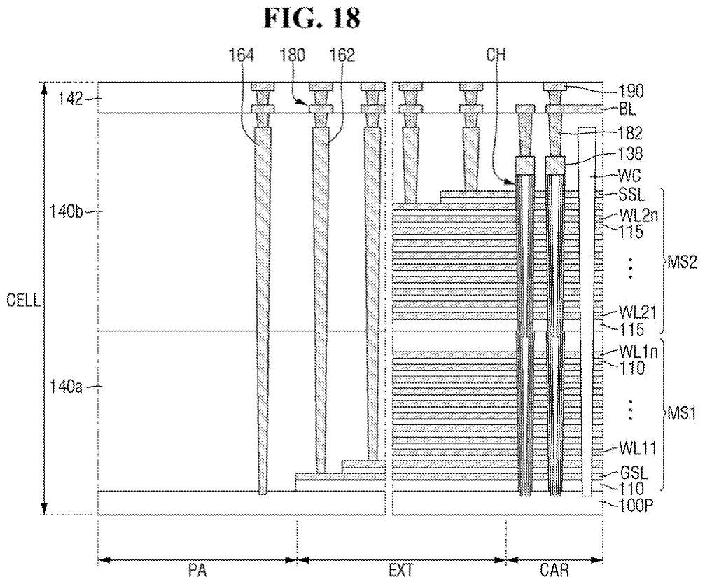

Referring to FIG. 18, the gate contact 162, the first source contact 164, the bit-line contact 182, the bit-line BL, and the cell wiring structure 180 may be formed on the mold structure MS1 and MS2.

A plurality of gate contacts 162 may be respectively connected to the plurality of gate electrodes GSL, WL11 to WL1n, WL21 to WL2n, and SSL. The first source contact 164 may be connected to the base substrate 100P. The bit-line BL may be formed on the second interlayer insulating film 140b. The bit-line BL may be electrically connected to the channel structures CH via the bit-line contact 182. The cell wiring structure 180 may be electrically connected to the bit-line BL and the gate contact 162.

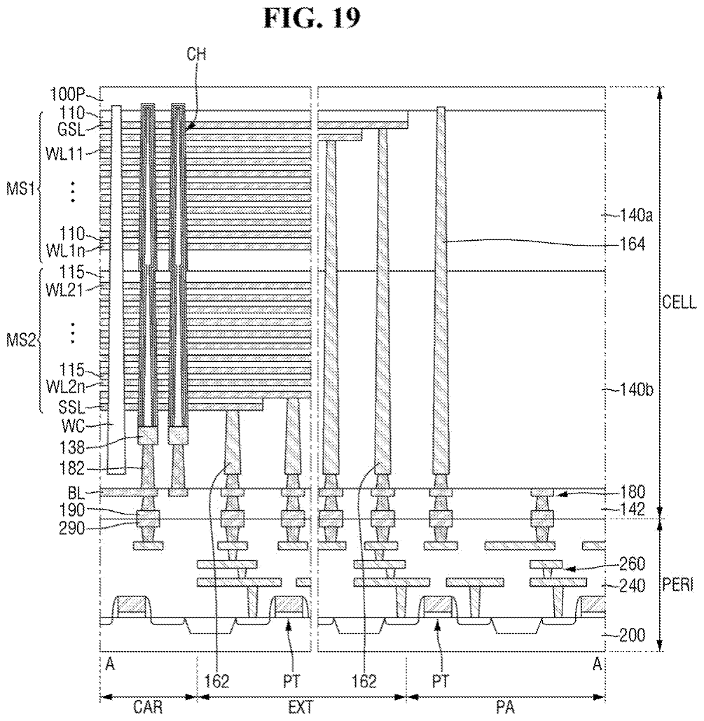

Referring to FIG. 19, the cell structure CELL may be stacked on the peripheral circuit structure PERI. In some embodiments, the cell structure CELL and the peripheral circuit structure PERI may be stacked on top of each other so that the front face of the base substrate 100P and the front face of the peripheral circuit substrate 200 face each other. In an implementation, the cell wiring structure 180 may be stacked on the peripheral circuit wiring structure 260.

In one example, the first bonding metal 190 formed as the uppermost metal layer of the cell structure CELL and the second bonding metal 290 formed as the uppermost metal layer of the peripheral circuit structure PERI may be bonded to each other. When each of the first bonding metal 190 and the second bonding metal 290 is made of copper (Cu), the bonding scheme may be a Cu—Cu bonding scheme. In another example, each of the first bonding metal 190 and the second bonding metal 290 may be made of each of various other metals such as aluminum (Al) or tungsten (W).

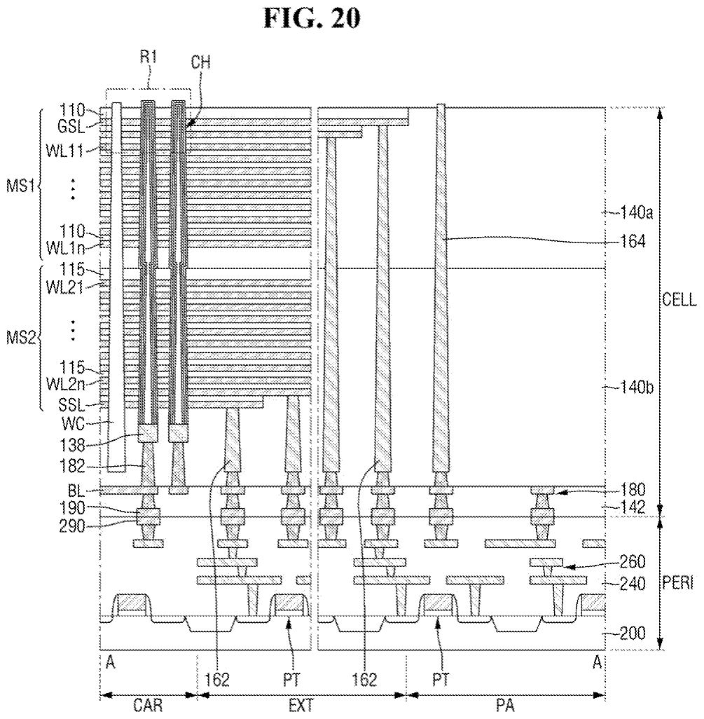

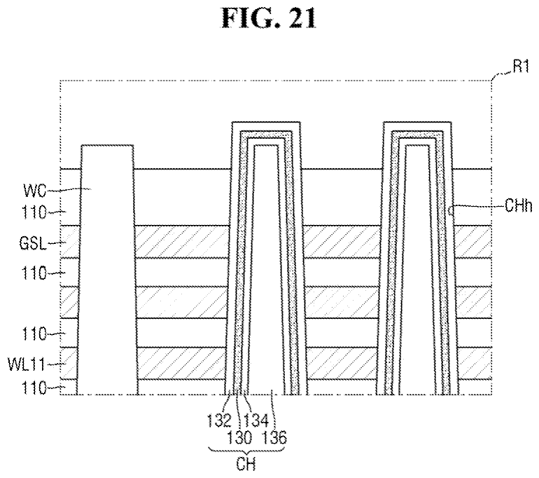

Referring to FIG. 20 and FIG. 21, one end of the channel structure CH may be exposed. For reference, FIG. 21 is an enlarged view to illustrate a R1 area in FIG. 20. In an implementation, a planarization process or a recess process may be performed on a back face of the base substrate 100P. Thus, at least a portion of the base substrate 100P may be removed so that one end of the gate dielectric film 132 may be exposed. In some embodiments, the base substrate 100P may be removed.

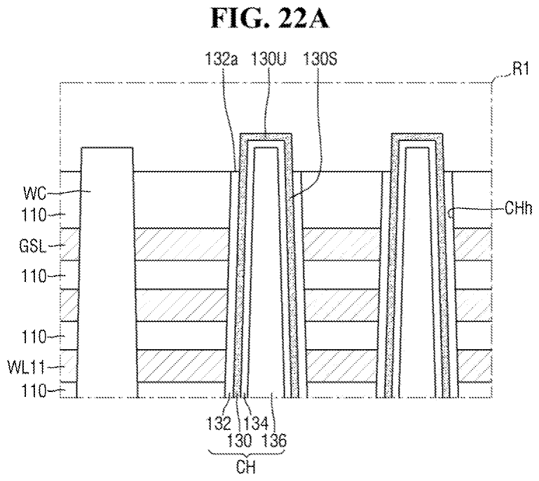

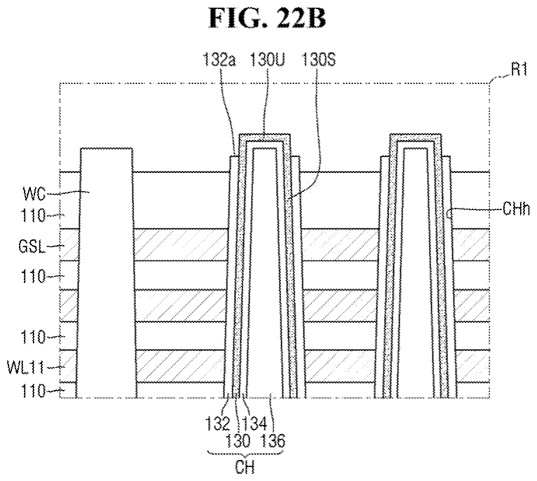

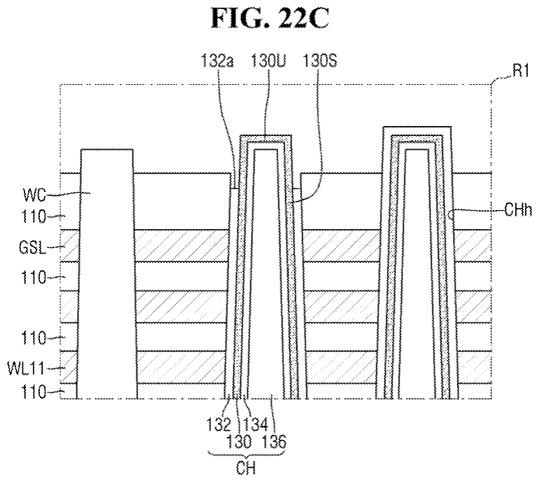

Referring to FIG. 22A to FIG. 22C, one end of the semiconductor film 130 may be exposed. In an implementation, a recess process may be performed on the gate dielectric film 132. As the recess process is performed, at least a portion of the exposed one end (e.g., an upper end) of the gate dielectric film 132 may be removed. Thus, one end of the semiconductor film 130 may not be covered with the gate dielectric film 132.

The recess process on the gate dielectric film 132 may be performed in various ways. In one example, as shown in FIG. 22A, a topmost surface 132a of the gate dielectric film 132 may be coplanar with the first face 100a of the cell substrate 100. In another example, as shown in FIG. 22B, the topmost surface 132a of the gate dielectric film 132 may be positioned at a higher level than that of the first face 100a of the cell substrate 100. In still another example, as shown in FIG. 22C, the topmost surface 132a of the gate dielectric film 132 may be positioned at a lower level than that of the first face 100a of the cell substrate 100.

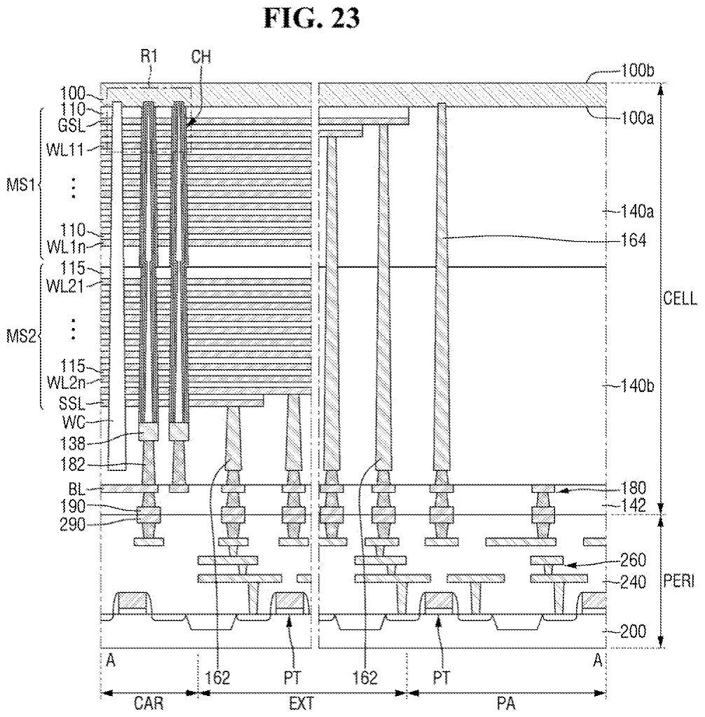

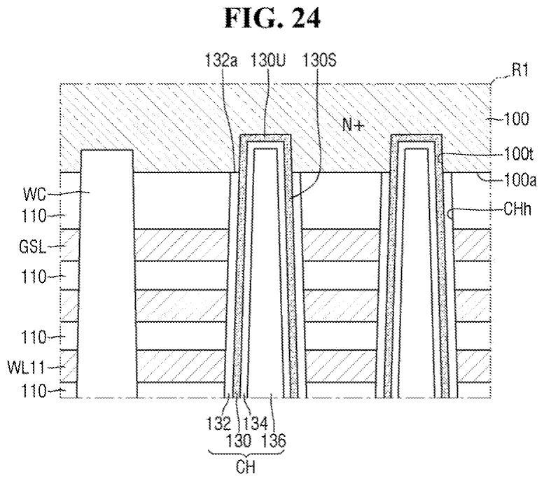

Referring to FIG. 23 and FIG. 24, the cell substrate 100 connected to the semiconductor film 130 may be formed. For reference, FIG. 24 is an enlarged view to illustrate a R1 area of FIG. 23.

In an implementation, the cell substrate 100 may be deposited on a surface of the first mold insulating film 110 from which the base substrate 100P has been removed. Thus, the cell substrate 100 connected to the semiconductor film 130 may be formed. The cell substrate 100 may include the first face 100a on which the channel structure CH and the gate electrodes GSL, WL11 to WL1n, WL21 to WL2n, and SSL are disposed, and the second face 100b opposite to the first face 100a.

In some embodiments, the cell substrate 100 may contain impurities. In an implementation, the cell substrate 100 may include N-type impurities, such as phosphorus (P) or arsenic (As). In some embodiments, the cell substrate 100 may include poly-Si doped with the N-type impurities.

As the semiconductor film 130 connected to the cell substrate 100 is formed via the above steps, the semiconductor film 130 may extend through the first face 100a of the cell substrate 100. In an implementation, at least a portion (e.g., a top portion) of the semiconductor film 130 may conformally extend along a profile of the substrate trench 100t. Further, the sidewall portion 130S of the semiconductor film 130 may linearly extend through the cell substrate 100 and the first mold stack MS1. In an implementation, as shown in FIG. 24, the side surface of the channel hole CHh and the side surface of the substrate trench 100t may continuously extend.

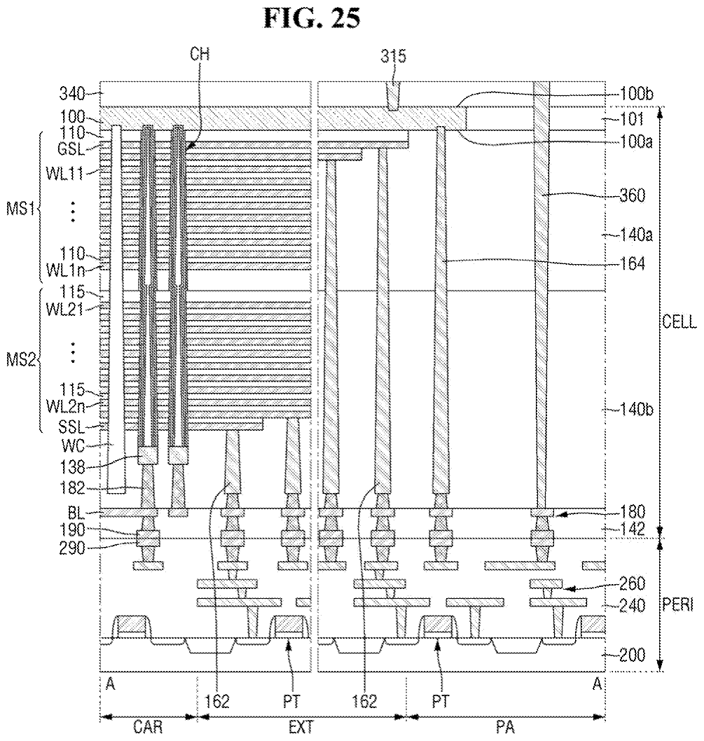

Referring to FIG. 25, the second source contact 315 and contact plug 360 may be formed. The second source contact 315 may be electrically connected to the cell substrate 100. In an implementation, the third interlayer insulating film 340 covering the cell substrate 100 and the insulating substrate 101 may be formed on the second face 100b of the cell substrate 100. The second source contact 315 may extend through the third interlayer insulating film 340 connected to the cell substrate 100.

The contact plug 360 may be electrically connected to the cell wiring structure 180. In an implementation, the contact plug 360 may extend through the third interlayer insulating film 340, the insulating substrate 101, the first interlayer insulating film 140a, and the second interlayer insulating film 140b connected to the cell wiring structure 180.

Next, referring to FIG. 4, the input/output wiring structure 380 and the capping insulating film 342 may be formed on the third interlayer insulating film 340. Thus, the semiconductor memory device as described above using FIG. 3 to FIG. 6B may be manufactured.

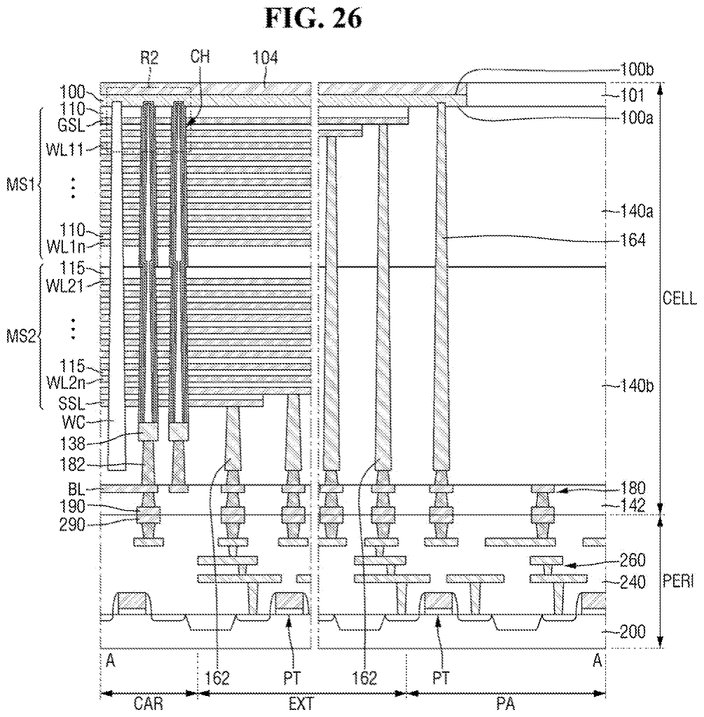

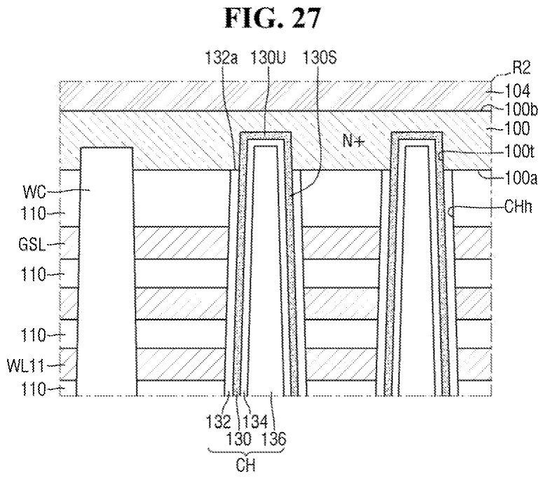

FIG. 26 and FIG. 27 are diagrams of stages in a method for manufacturing a semiconductor memory device according to example embodiments. For the convenience of description, those duplicate with descriptions as set forth above with reference to FIG. 1 to FIG. 25 are briefly described or omitted.

Referring to FIG. 26 and FIG. 27, the conductive plate 104 may be formed on the second face 100b of the cell substrate 100. For reference, FIG. 26 is a diagram of an intermediate structure corresponding to an intermediate step to illustrate a step after FIG. 23. Further, FIG. 27 is an enlarged view to illustrate a R1 area in FIG. 26.

The conductive plate 104 may extend along the second face 100b of the cell substrate 100. The conductive plate 104 may be electrically connected to the cell substrate 100. In an implementation, the bottom face of the conductive plate 104 may contact the second face 100b of the cell substrate 100. The conductive plate 104 may include a conductive material, e.g., a metal such as tungsten (W), cobalt (Co), nickel (Ni), or metal silicide.

Subsequently, the steps as described above using FIG. 25 and FIG. 4 may be performed. Thus, the semiconductor memory device as described above using FIG. 7 and FIG. 8 may be manufactured.

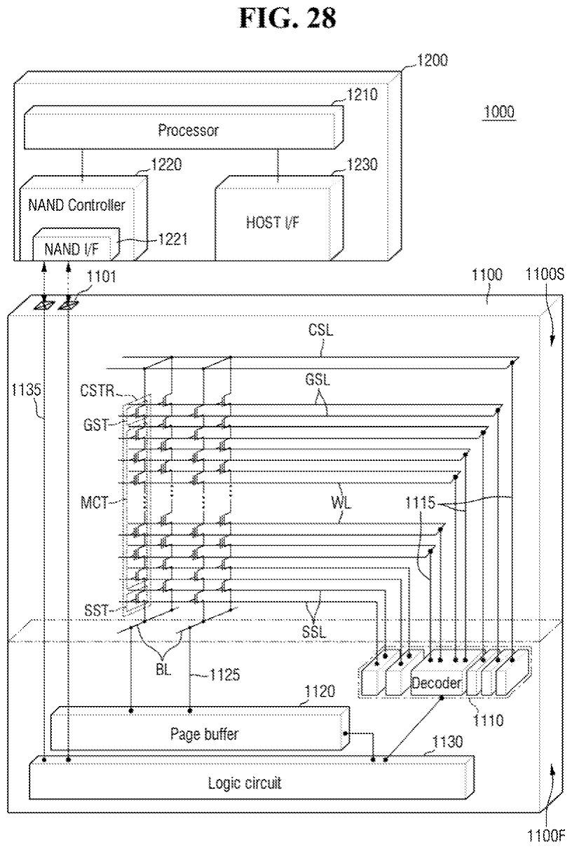

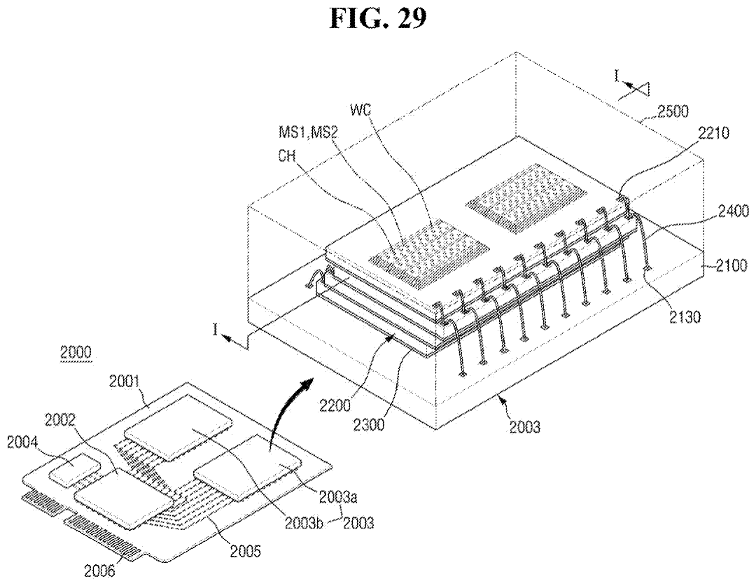

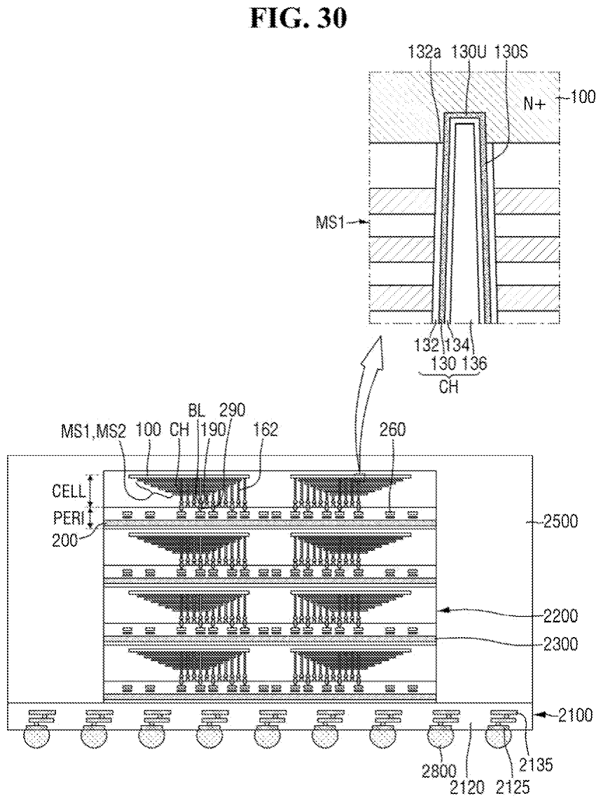

Hereinafter, referring to FIG. 1 to FIG. 10 and FIG. 28 to FIG. 30, an electronic system including the semiconductor memory device according to some embodiments is described. FIG. 28 is a block diagram of an electronic system according to example embodiments. FIG. 29 is a perspective view of an electronic system according to example embodiments. FIG. 30 is a schematic cross-sectional view taken along I-I of FIG. 29.

Referring to FIG. 28, an electronic system 1000 according to some embodiments may include a semiconductor memory device 1100 and a controller 1200 electrically connected to the semiconductor memory device 1100. The electronic system 1000 may be a storage device storage device including one or a plurality of semiconductor devices 1100 or an electronic device electronic device including the storage device. In an implementation, the electronic system 1000 may be embodied as a solid state drive device (SSD), a Universal Serial Bus (USB), a computing system, a medical device, or a communication device including one or a plurality of semiconductor memory devices 1100.

The semiconductor memory device 1100 may be embodied as a non-volatile memory device (e.g., a NAND flash memory device). The semiconductor memory device 1100 may be embodied, e.g., the semiconductor device as described above with reference to FIGS. 1 to 10. The semiconductor memory device 1100 may include a first structure 1100F and a second structure 1100S on the first structure 1100F.

The first structure 1100F may be a peripheral circuit structure including a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1). The first structure 1100F may be embodied as, e.g., the peripheral circuit structure PERI as described above with reference to FIGS. 1 to 10.

The second structure 1100S may include the common source line CSL, the plurality of bit-lines BL and the plurality of cell strings CSTR as above-described with reference to FIG. 2. The cell strings CSTR may be connected to the decoder circuit 1110 via the word-line WL, at least one string select line SSL, and at least one ground select line GSL. Further, the cell strings CSTR may be connected to the page buffer 1120 via the bit-lines BL. The second structure 1100S may be embodied as, e.g., the cell structure CELL as described above using FIGS. 1 to 10.

In some embodiments, the common source line CSL and the cell string CSTR may be electrically connected to the decoder circuit 1110 via a first connection wiring 1115 extending from the first structure 1100F to the second structure 1100S. The first connection wiring 1115 may be embodied as, e.g., the gate contacts 162 as described above using FIGS. 1 to 10. In an implementation, the cell contact 150 may electrically connect the gate electrodes GSL, WL, and SSL to the decoder circuit 1110 (e.g., the row decoder 33 of FIG. 1).

In some embodiments, the bit-lines BL may be electrically connected to the page buffer 1120 via a second connection wiring 1125. The second connection wiring 1125 may be embodied as, e.g., the bit-line contact 182 as described above with reference to FIGS. 1 to 10. In an implementation, the bit-line contact 182 may electrically connect the bit-lines BL to the page buffer 1120 (e.g., the page buffer 35 in FIG. 1).

The semiconductor memory device 1100 may communicate with the controller 1200 via an input/output pad 1101 electrically connected to the logic circuit 1130 (e.g., the control logic 37 in FIG. 1). The input/output pad 1101 may be electrically connected to the logic circuit 1130 via an input/output connection line 1135 extending from the first structure 1100F to the second structure 1100S. The connection line 1135 may be embodied as, e.g., the contact plug 360 as described with reference to FIGS. 1 to 10.

The controller 1200 may include a processor 1210, a NAND controller 1220, and a host interface 1230. In some embodiments, the electronic system 1000 may include a plurality of semiconductor memory devices 1100. In this case, the controller 1200 may control the plurality of semiconductor memory devices 1100.

The processor 1210 may control overall operations of the electronic system 1000 including the controller 1200. The processor 1210 may operate based on predefined firmware, and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data written to memory cell transistors MCT of the semiconductor memory device 1100, and data read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIG. 29 and FIG. 30, an electronic system according to some embodiments may include a main substrate 2001, a main controller 2002 mounted on the main substrate 2001, at least one semiconductor package 2003, and at least one DRAM 2004. The semiconductor package 2003 and the DRAM 2004 may be connected to the main controller 2002 via line patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some embodiments, the electronic system 2000 may communicate with the external host using one of interfaces such as USB (Universal Serial Bus), PCI-Express (Peripheral Component Interconnect Express), SATA (Serial Advanced Technology Attachment), or M-Phy for UFS (Universal Flash Storage). In some embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 on a bottom face of each of the semiconductor chips 2200, a connection structure 2400 electrically connecting the semiconductor chips 2200 and the package substrate 2100 to each other, and a molding layer 2500 on the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may be embodied as the input/output pad 1101 in FIG. 28.

In some embodiments, the connection structure 2400 may be embodied as a bonding wire that may electrically connect the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be connected to each other via a line formed in the interposer substrate.

In some embodiments, the package substrate 2100 may be embodied as a printed circuit board. The package substrate 2100 may include a package substrate body 2120, the package upper pads on a top face of the package substrate body 2120, package lower pads 2125 on a bottom face of the package substrate body 2120, or exposed through the bottom face thereof, and internal lines 2135 in the package substrate body 2120 and may electrically connect the upper pads 2130 and the lower pads 2125 to each other. The upper pads 2130 may be electrically connected to the connection structures 2400. The lower pads 2125 may be connected to the line patterns 2005 of the main substrate 2010 of the electronic system 2000 via conductive connectors 2800 as shown in FIG. 29.

In the electronic system according to some embodiments, each of the semiconductor chips 2200 may include the semiconductor memory device as described above using FIGS. 1 to 10. In an implementation, each of the semiconductor chips 2200 may include the peripheral circuit structure PERI and the cell structure CELL stacked on the peripheral circuit structure PERI. By way of example, the peripheral circuit structure PERI may include the peripheral circuit substrate 200 and the peripheral circuit wiring structure 260 as described above using FIGS. 3 and 4. Further, by way of example, the cell structure CELL may include the cell substrate 100, the mold structure MS1 and MS2, the channel structure CH, the bit-line BL, and the gate contact 162 as described above using FIG. 3 and FIG. 4. Further, the channel structure CH may include the gate dielectric film 132, the semiconductor film 130, the variable resistance film 134, and the filling insulating film 136 as described above using FIG. 5A to FIG. 5E. The peripheral circuit structure PERI and the cell structure CELL may be bonded to each other via the first bonding metal 190 and the second bonding metal 290.

By way of summation and review, the present disclosure relates to a semiconductor memory device including three-dimensionally arranged memory cells, a method for manufacturing the same, and an electronic system including the same.

A semiconductor memory device including memory cells arranged in a three-dimensional manner instead of memory cells arranged in a two-dimensional manner has been proposed as one of the schemes for increasing the data storage capacity of the semiconductor memory device.

A semiconductor memory device with improved integration and memory capacity is disclosed. Another technical purpose of the present disclosure is to provide a method for manufacturing a semiconductor memory device with improved integration and memory capacity.

Still another technical purpose of the present disclosure is to provide an electronic system including a semiconductor memory device with improved integration and memory capacity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor memory device, comprising:
a peripheral circuit structure; and
a cell structure stacked on the peripheral circuit structure,
wherein the cell structure includes:
a cell substrate including a first face facing the peripheral circuit structure and a second face opposite the first face;
a first mold stack including a plurality of first gate electrodes sequentially stacked on the first face;
a channel hole extending through the plurality of first gate electrodes; and
a channel structure including a gate dielectric film, a semiconductor film, and a variable resistance film sequentially stacked in the channel hole,
wherein the semiconductor film includes:
a sidewall portion intersecting the first face and the plurality of first gate electrodes; and
a top plate portion extending from the sidewall portion in the cell substrate in a parallel manner to the first face,
wherein the sidewall portion of the semiconductor film extends linearly through the cell substrate and the first mold stack, and
wherein the top plate portion of the semiconductor film is exposed through the gate dielectric film and is connected to the cell substrate.

2. The semiconductor memory device as claimed in claim 1, wherein each of the gate dielectric film, the semiconductor film, and the variable resistance film conformally extends along a profile of the channel hole.

3. The semiconductor memory device as claimed in claim 1, wherein the cell substrate includes poly-Si doped with N-type impurities.

4. The semiconductor memory device as claimed in claim 1, wherein the variable resistance film includes a transition metal oxide.

5. (canceled)

6. The semiconductor memory device as claimed in claim 1, wherein the channel structure further includes a filling insulating film on the variable resistance film filling the channel hole.

7. (canceled)

8. The semiconductor memory device as claimed in claim 1, further comprising an input/output wiring structure on the second face and electrically connected to the cell substrate.

9. The semiconductor memory device as claimed in claim 1, wherein the cell structure further includes a conductive plate extending along the second face.

10. The semiconductor memory device as claimed in claim 1, wherein:
the cell structure further includes a second mold stack including a plurality of second gate electrodes sequentially stacked between the peripheral circuit structure and the first mold stack, and
the channel hole extends through the plurality of first gate electrodes and the plurality of second gate electrodes.

11. The semiconductor memory device as claimed in claim 10, wherein the channel hole has a step between the first mold stack and the second mold stack.

12. A semiconductor memory device, comprising:
a peripheral circuit structure; and
a cell structure stacked on the peripheral circuit structure,
wherein the cell structure includes:
a cell substrate including a first face facing the peripheral circuit structure and a second face opposite to the first face;
a plurality of gate electrodes sequentially stacked on the first face;
a semiconductor film intersecting the plurality of gate electrodes and connected to the cell substrate;
a gate dielectric film extending along an outer side surface of the semiconductor film and between the semiconductor film and the plurality of gate electrodes; and
a variable resistance film extending along an inner side surface of the semiconductor film,
wherein the gate dielectric film does not extend along a surface of the semiconductor film parallel to the first face.

13. (canceled)

14. The semiconductor memory device as claimed in claim 12, wherein a topmost surface of the gate dielectric film is coplanar with the first face.

15. The semiconductor memory device as claimed in claim 12, wherein a vertical level of a topmost surface of the gate dielectric film is higher than a vertical level of the first face.

16. The semiconductor memory device as claimed in claim 12, wherein a vertical level of a topmost surface of the gate dielectric film is lower than a vertical level of the first face.

17. The semiconductor memory device as claimed in claim 16, wherein the cell substrate includes a protrusion protruding from the first face toward the gate dielectric film.

18. The semiconductor memory device as claimed in claim 12, wherein:
the semiconductor film has a cup shape, and
the cell structure further includes a filling insulating film filling an inner space defined by the variable resistance film.

19. The semiconductor memory device as claimed in claim 18, wherein the filling insulating film extends through the variable resistance film.

20. The semiconductor memory device as claimed in claim 18, wherein a topmost surface of the filling insulating film is positioned within the cell substrate.

21. The semiconductor memory device as claimed in claim 12, wherein the cell structure includes:
a bit-line between the peripheral circuit structure and the semiconductor film, the bit-line being connected to the semiconductor film;
a plurality of gate contacts between the peripheral circuit structure and the plurality of gate electrodes, the plurality of gate contacts being respectively connected to the plurality of gate electrodes; and
a cell wiring structure bonded onto the peripheral circuit structure, the cell wiring structure being electrically connected to the bit-line and the plurality of gate contacts.

22. The semiconductor memory device as claimed in claim 21, wherein the peripheral circuit structure includes:
a peripheral circuit substrate;
a peripheral circuit element on the peripheral circuit substrate; and
a peripheral circuit wiring structure on the peripheral circuit substrate electrically connecting the cell wiring structure and the peripheral circuit element.

23-26. (canceled)

27. An electronic system, comprising:
a main substrate;
a semiconductor memory device on the main substrate, the semiconductor memory device including a peripheral circuit structure and a cell structure stacked on the peripheral circuit structure; and
a controller on the main substrate, the controller electrically connected to the semiconductor memory device,
wherein the cell structure includes:
a cell substrate including a first face facing the peripheral circuit structure and a second face opposite to the first face, the cell substrate being electrically connected to the controller;
a plurality of gate electrodes sequentially stacked on the first face;
a semiconductor film intersecting the plurality of gate electrodes and connected to the cell substrate;
a gate dielectric film extending along an outer side surface of the semiconductor film and between the semiconductor film and the plurality of gate electrodes;
a variable resistance film extending along an inner side surface of the semiconductor film,
wherein the gate dielectric film does not extend along a surface of the semiconductor film parallel to the first face.

28-30. (canceled)
